(19) United States
(12) Patent Application Publication
(10) Pub. No.: US 2025/0287598 A1
(43) Pub. Date: Sep. 11, 2025

(54) SEMICONDUCTOR MEMORY DEVICE

(71) Applicant: Kioxia Corporation, Tokyo (JP)

(72) Inventor: Nobuyuki MOMO, Yokohama Kanagawa (JP)

(73) Assignee: Kioxia Corporation, Tokyo (JP)

(21) Appl. No.: 18/828,593

(22) Filed: Sep. 9, 2024

(30) Foreign Application Priority Data
Mar. 8, 2024 (JP) 2024-035464

(51) Int. Cl. H10B 43/40; H01L 23/00; H01L 25/00; H01L 25/065; H01L 25/18; H10B 41/41; H10B 80/00

(52) U.S. Cl. CPC H10B 43/40; H01L 24/08; H01L 24/80; H01L 25/0657; H01L 25/18; H01L 25/50; H10B 41/41; H10B 80/00; H01L 2224/08145; H01L 2224/80895; H01L 2224/80896; H01L 2924/1431; H01L 2924/14511

(57) ABSTRACT

A semiconductor memory device comprises a first semiconductor chip and a second semiconductor chip. The first semiconductor chip comprises: a first insulating member extending in a first direction to a first position between a first surface and a second surface of the semiconductor substrate from the first surface, and including a first portion and a second portion separated in a second direction; a second insulating member extending in the first direction from the second surface to the first position, and including a third portion provided at a position overlapping the first portion and a fourth portion provided at a position overlapping the second portion; an object circuit provided in a region between the first portion and the second portion; a control circuit adjusting electrical characteristics of the object circuit; and a plurality of transistors provided in the first surface.

### CROSS-REFERENCE TO RELATED APPLICATIONS

This application is based upon and claims the benefit of Japanese Patent Application No. 2024-035464, filed on Mar. 8, 2024, the entire contents of which are incorporated herein by reference.

### BACKGROUND

### Field

The present embodiments relate to semiconductor memory devices.

### Description of the Related Art

There is known a semiconductor memory device comprising: a substrate; a plurality of conductive layers stacked in a direction intersecting a surface of this substrate; a semiconductor layer facing these plurality of conductive layers; and a gate insulating layer provided between the conductive layers and the semiconductor layer. The gate insulating layer comprises a memory portion capable of storing data, such as an insulating charge accumulating layer of silicon nitride (SiN), or the like, or a conductive charge accumulating layer of the likes of a floating gate, for example.

### BRIEF DESCRIPTION OF THE DRAWINGS

FIG. 1 is a schematic block diagram showing a configuration of a memory die MD according to a first embodiment.

FIG. 2 is a schematic circuit diagram showing a part of the configuration of the memory die MD.

FIG. 3 is a schematic circuit diagram showing configurations of a voltage generating circuit VG, a driver circuit DRV, and a row decoder RD.

FIG. 4 is a schematic circuit diagram showing configurations of a row control circuit RowC and a block decoder BLKD.

FIG. 5 is a schematic exploded perspective view showing a configuration example of a semiconductor memory device according to the first embodiment.

FIG. 6 is a schematic top view showing a configuration example of a chip C_{M}.

FIG. 7 is a schematic cross-sectional view showing a part of the configuration of the memory die MD.

FIG. 8 is a schematic cross-sectional view showing a part of the configuration of the memory die MD.

FIG. 9 is a schematic top view showing a part of the configuration of the chip C_{M}.

FIG. 10 is a schematic cross-sectional view showing a part of the configuration of the chip C_{M}.

FIG. 11 is a schematic plan view showing a configuration example of a hook-up region R_{HU}.

FIG. 12 is a schematic bottom view showing a configuration example of a chip C_{P}.

FIG. 13 is a schematic bottom view showing a part of a configuration in a row control circuit region R_{RC}.

FIG. 14 is a schematic bottom view showing a part of the configuration in the row control circuit region R_{RC}.

FIG. 15 is a circuit diagram exemplifying a circuit of a part of a plurality of transistors in a semiconductor substrate 200 and an object circuit connected to this circuit, according to the first embodiment.

FIG. 16 is a schematic cross-sectional view showing a part of a configuration of the semiconductor memory device according to the first embodiment.

FIG. 17 is a schematic cross-sectional view for explaining a method of manufacturing a CMOS portion of the chip C_{P}.

FIG. 18 is a schematic cross-sectional view for explaining the method of manufacturing a CMOS portion of the chip C_{P}.

FIG. 19 is a schematic cross-sectional view for explaining the method of manufacturing a CMOS portion of the chip C_{P}.

FIG. 20 is a schematic cross-sectional view for explaining the method of manufacturing a CMOS portion of the chip C_{P}.

FIG. 21 is a schematic cross-sectional view for explaining the method of manufacturing a CMOS portion of the chip C_{P}.

FIG. 22 is a schematic cross-sectional view for explaining the method of manufacturing a CMOS portion of the chip C_{P}.

FIG. 23 is a schematic cross-sectional view for explaining the method of manufacturing a CMOS portion of the chip C_{P}.

FIG. 24 is a schematic cross-sectional view for explaining a method of manufacturing by which wafers W_{M}, W_{P} are bonded.

FIG. 25 is a schematic cross-sectional view for explaining the method of manufacturing by which wafers W_{M}, W_{P} are bonded.

FIG. 26 is a schematic cross-sectional view for explaining a method of manufacturing a semiconductor substrate 200 portion of the chip C_{P}.

FIG. 27 is a schematic cross-sectional view for explaining the method of manufacturing a semiconductor substrate 200 portion of the chip C_{P}.

FIG. 28 is a schematic cross-sectional view for explaining the method of manufacturing a semiconductor substrate 200 portion of the chip C_{P}.

FIG. 29 is a schematic cross-sectional view for explaining the method of manufacturing a semiconductor substrate 200 portion of the chip C_{P}.

FIG. 30 is a schematic cross-sectional view for explaining the method of manufacturing a semiconductor substrate 200 portion of the chip C_{P}.

FIG. 31 is a schematic cross-sectional view for explaining the method of manufacturing a semiconductor substrate 200 portion of the chip C_{P}.

FIG. 32 is a schematic cross-sectional view for explaining the method of manufacturing a semiconductor substrate 200 portion of the chip C_{P}.

FIG. 33 is a schematic cross-sectional view showing a part of a configuration of a memory die MD according to a comparative example.

FIG. 34 is a schematic cross-sectional view showing a part of the configuration of the memory die MD according to the comparative example.

FIG. 35 is a schematic cross-sectional view showing a connection relationship between a part of a plurality of transistors in a semiconductor substrate 200 and a configuration of an object circuit connected to these transistors, according to the comparative example.

FIG. 36 is a circuit diagram exemplifying a circuit of a part of the plurality of transistors in the semiconductor substrate 200 and the object circuit connected to this circuit, according to the comparative example.

FIG. 37 is a plan view schematically showing circuit block areas occupied by configurations of the circuit of a part of the plurality of transistors in the semiconductor substrate 200 and the object circuit connected to this circuit, according to the comparative example.

FIG. 38 is a block diagram showing a separate input/output circuit where a foot switch FSW according to the first embodiment is used.

FIG. 39 is a schematic cross-sectional view showing a part of a configuration of a semiconductor memory device according to a second embodiment.

FIG. 40 is a schematic cross-sectional view showing a part of the configuration of the semiconductor memory device according to the second embodiment.

FIG. 41 is a schematic bottom view showing configuration of a resistance element shown in FIGS. 39 and 40.

FIG. 42 is an explanatory diagram for explaining a variable resistance mechanism of the resistance element shown in FIG. 39.

FIG. 43 is a schematic cross-sectional view for explaining a method of manufacturing a portion of an object circuit according to the second embodiment.

FIG. 44 is a schematic cross-sectional view for explaining the method of manufacturing a portion of an object circuit according to the second embodiment.

FIG. 45 is a schematic cross-sectional view showing a part of a configuration of a semiconductor memory device according to a comparative example.

FIG. 46 is a schematic bottom view showing configuration of a resistance element shown in FIG. 45.

FIG. 47 is a schematic cross-sectional view showing a part of a configuration of a semiconductor memory device according to a modified example of the second embodiment.

FIG. 48 is a schematic bottom view showing configuration of a resistance element shown in FIG. 47.

FIG. 49 is a schematic cross-sectional view showing configuration of the resistance element shown in FIG. 47.

FIG. 50 is an explanatory diagram for explaining a variable resistance mechanism of the resistance element shown in FIG. 47.

FIG. 51 is a schematic cross-sectional view for explaining a method of manufacturing a portion of an object circuit according to the modified example of the second embodiment.

FIG. 52 is a schematic cross-sectional view for explaining the method of manufacturing a portion of an object circuit according to the modified example of the second embodiment.

FIG. 53 is a schematic cross-sectional view showing a part of a configuration of a semiconductor memory device according to a comparative example.

FIG. 54 is a schematic bottom view showing configuration of a resistance element shown in FIG. 53.

FIG. 55 is a block diagram showing an example of specific configuration of a VPGM generating circuit 940 in which the object circuit according to the second embodiment is used.

FIG. 56 is a circuit diagram for explaining a ladder circuit.

FIG. 57 is a schematic cross-sectional view for explaining a method of manufacturing a semiconductor substrate 200 portion of a chip C_{P} according to another embodiment.

### DETAILED DESCRIPTION

A semiconductor memory device according to one embodiment comprises a first semiconductor chip and a second semiconductor chip that are connected to each other. The first semiconductor chip comprises: a semiconductor substrate having a first surface and a second surface, the first surface and the second surface intersecting a first direction; a first insulating member that extends in the first direction from the first surface of the semiconductor substrate to a first position between the first surface and the second surface of the semiconductor substrate, and includes a first portion and a second portion, the first portion and the second portion being separated in a second direction intersecting the first direction; a second insulating member that extends in the first direction from the second surface of the semiconductor substrate to the first position of the semiconductor substrate, and includes a third portion and a fourth portion, the third portion being provided at a position overlapping the first portion viewed from the first direction, and the fourth portion being provided at a position overlapping the second portion viewed from the first direction; an object circuit provided in a region between the first portion and the second portion viewed from the first direction, of the semiconductor substrate; a control circuit that adjusts electrical characteristics of the object circuit; a plurality of transistors provided in the first surface of the semiconductor substrate; a plurality of first contacts extending in the first direction and connected to the plurality of transistors; and a plurality of first bonding electrodes electrically connected to the plurality of transistors via the plurality of first contacts. The second semiconductor chip comprises: a plurality of first conductive layers arranged in the first direction; a semiconductor column extending in the first direction and facing the plurality of first conductive layers; a plurality of second contacts extending in the first direction and connected to the plurality of first conductive layers; and a plurality of second bonding electrodes connected to the plurality of first conductive layers via the plurality of second contacts.

The first semiconductor chip and the second semiconductor chip are disposed so that the plurality of first bonding electrodes face the plurality of second bonding electrodes.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been serially connected, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are serially connected, and the second configuration is connected to the third configuration via the first configuration.

Moreover, in the present specification, when a circuit, or the like, is said to “make electrically continuous” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to a surface of a substrate will be referred to as an X-direction, a direction parallel to the surface of the substrate and perpendicular to the X-direction will be referred to as a Y-direction, and a direction perpendicular to the surface of the substrate will be referred to as a Z-direction.

Moreover, in the present specification, a direction lying along a certain plane will sometimes be referred to as a first direction, a direction intersecting the first direction along the certain plane will sometimes be referred to as a second direction, and a direction intersecting the certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to an external pad electrode connectable to a bonding wire. For example, in a memory die MD, an orientation of coming closer to the external pad electrode along the above-described Z-direction will be referred to as above, and an orientation of moving away from the external pad electrode along the Z-direction will be referred to as below. Moreover, when a lower surface or a lower end is referred to for a certain configuration, this will be assumed to mean a surface or end portion on an opposite side to the external pad electrode of this configuration, and when an upper surface or an upper end is referred to for a certain configuration, this will be assumed to mean a surface or end portion on an external pad electrode side of this configuration. Moreover, a surface intersecting the X-direction or the Y-direction will be referred to as a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

### First Embodiment

### Circuit Configuration of Memory Die MD

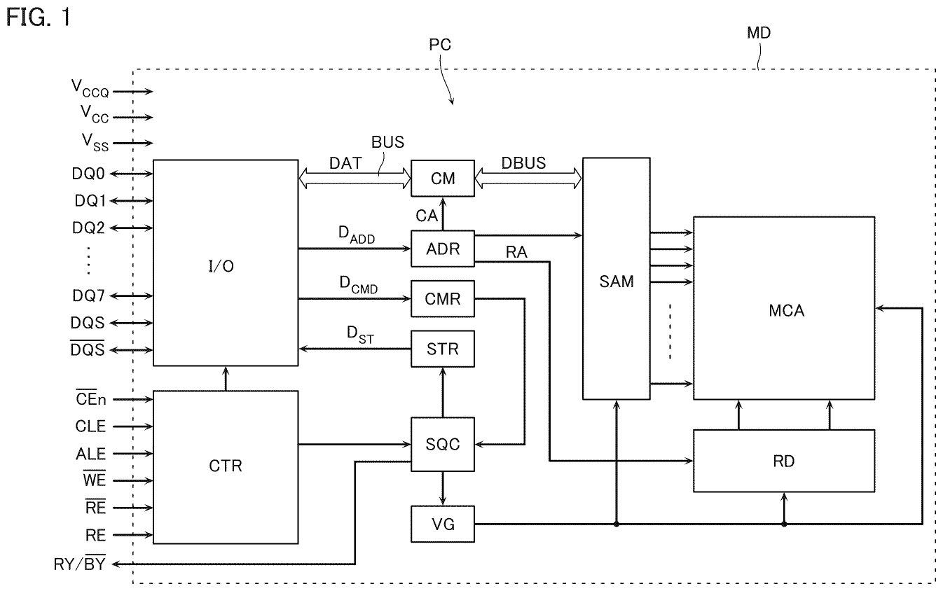

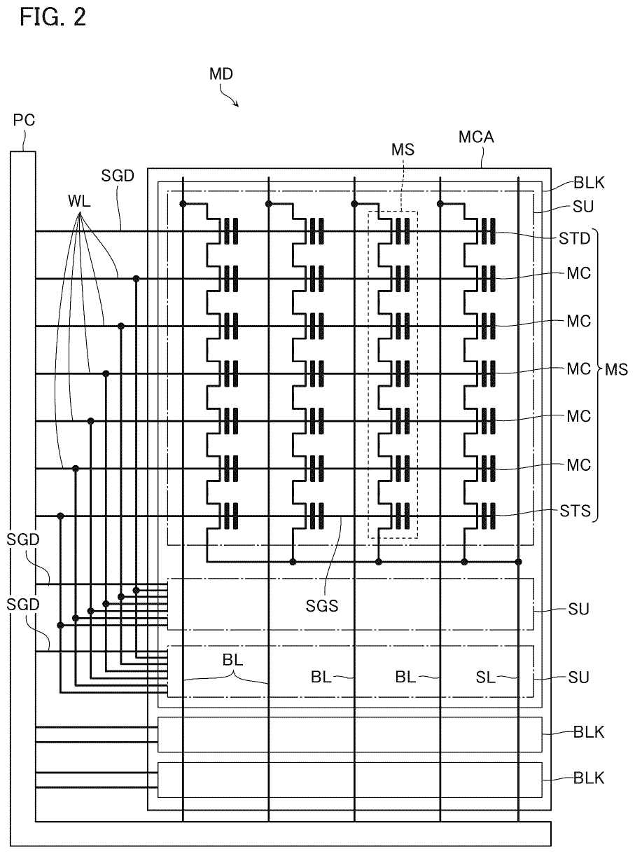

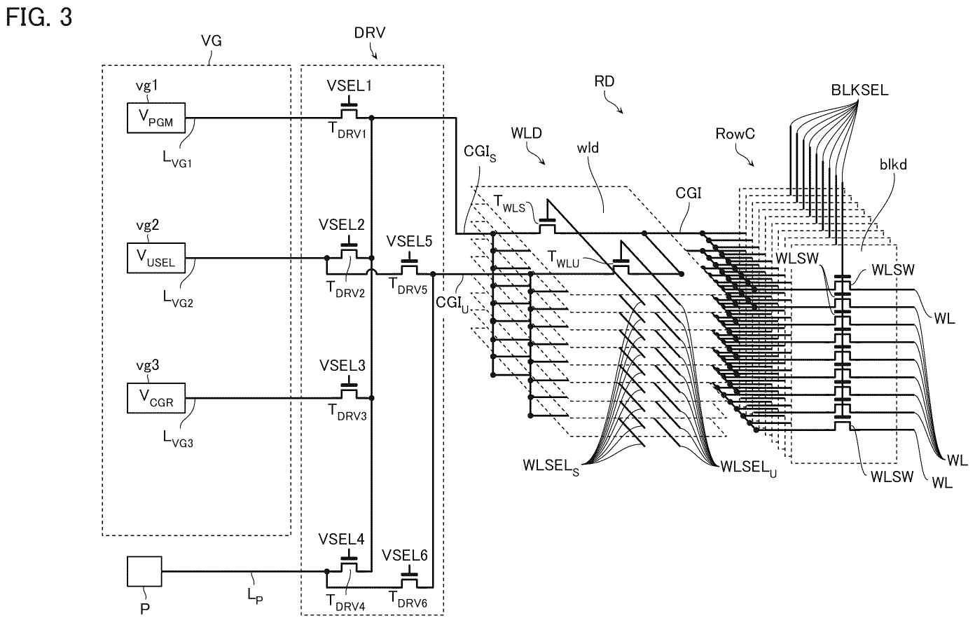

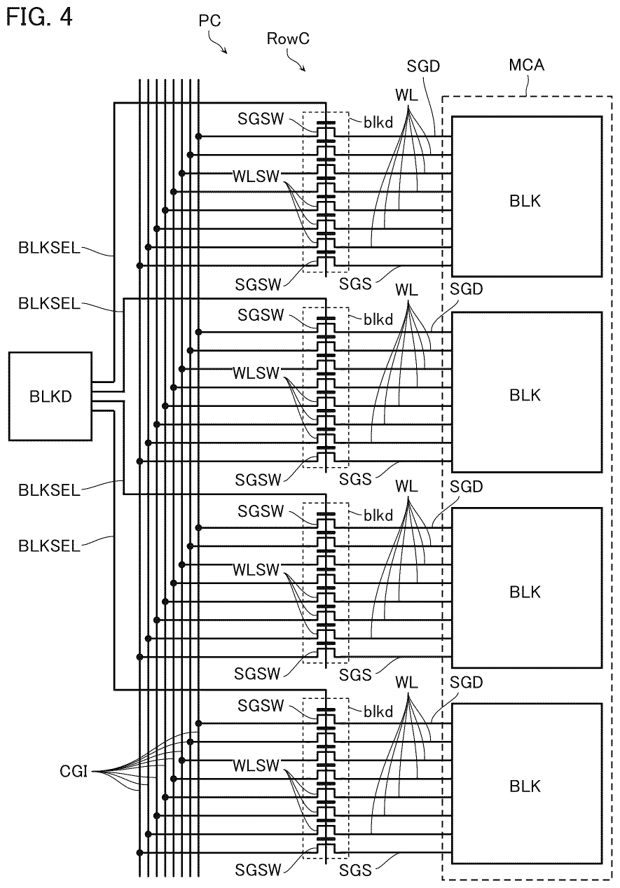

FIG. 1 is a schematic block diagram showing configuration of a memory die MD according to a first embodiment. FIG. 2 is a schematic circuit diagram showing a part of the configuration of the memory die MD. FIG. 3 is a schematic circuit diagram showing configurations of a voltage generating circuit VG, a driver circuit DRV, and a row decoder RD. FIG. 4 is a schematic circuit diagram showing configurations of a row control circuit RowC and a block decoder BLKD.

Note that in FIG. 1, a plurality of control terminals, and so on, are illustrated. The plurality of control terminals are sometimes indicated as a control terminal corresponding to a high active signal (a positive logic signal). Moreover, the plurality of control signals are sometimes indicated as a control terminal corresponding to a low active signal (a negative logic signal). Moreover, the plurality of control signals are sometimes indicated as a control terminal corresponding to both a high active signal and a low active signal. In FIG. 1, a symbol of a control terminal corresponding to a low active signal includes an overline (an overbar). In the present specification, a symbol of a control terminal corresponding to a low active signal includes a slash (“/”). Note that description of FIG. 1 is an exemplification, and that a specific mode is appropriately adjustable. For example, it is possible too for a part of or all of the high active signals to be configured as low active signals, or for a part of or all of the low active signals to be configured as high active signals.

As shown in FIG. 1, the memory die MD comprises a memory cell array MCA and a peripheral circuit PC. The peripheral circuit PC comprises the voltage generating circuit VG, the row decoder RD, a sense amplifier module SAM, and a sequencer SQC. Moreover, the peripheral circuit PC comprises a cache memory CM, an address register ADR, a command register CMR, and a status register STR. In addition, the peripheral circuit PC comprises an input/output control circuit I/O and a logic circuit CTR.

### Circuit Configuration of Memory Cell Array MCA

As shown in FIG. 2, the memory cell array MCA comprises a plurality of memory blocks BLK. These plurality of memory blocks BLK each comprise a plurality of string units SU. These plurality of string units SU each comprise a plurality of memory strings MS. One ends of these plurality of memory strings MS are each connected to the peripheral circuit PC via a bit line BL. Moreover, the other ends of these plurality of memory strings MS are each connected to the peripheral circuit PC via a common source line SL.

The memory string MS comprises a drain side select transistor STD, a plurality of memory cells MC (memory transistors), and a source side select transistor STS. The drain side select transistor STD, the plurality of memory cells MC, and the source side select transistor STS are connected in series between the bit line BL and the source line SL. Hereafter, the drain side select transistor STD and the source side select transistor STS will sometimes simply be referred to as select transistors (STD, STS).

The memory cell MC is a field effect type transistor. The memory cell MC comprises a semiconductor layer, a gate insulating film, and a gate electrode. The semiconductor layer functions as a channel region. The gate insulating film includes an electric charge accumulating film. A threshold voltage of the memory cell MC changes according to an amount of charge in the electric charge accumulating film. The memory cell MC stores 1 bit or a plurality of bits of data. Note that the gate electrodes of the plurality of memory cells MC corresponding to one memory string MS are connected with respective word lines WL. Each of these word lines WL is commonly connected to all of the memory strings MS in one memory block BLK.

The select transistors (STD, STS) are field effect type transistors. The select transistors (STD, STS) each comprise a semiconductor layer, a gate insulating film, and a gate electrode. The semiconductor layer functions as a channel region. The gate insulating film may include an electric charge accumulating film. The gate electrode of the drain side select transistor STD is connected with a drain side select gate line SGD, and the gate electrode of the source side select transistor STS is connected with a source side select gate line SGS. One drain side select gate line SGD is commonly connected to all of the memory strings MS in one string unit SU. One source side select gate line SGS is commonly connected to all of the memory strings MS in one memory block BLK. Note that the drain side select gate line SGD and the source side select gate line SGS will each sometimes be referred to as a select gate line SG.

### Circuit Configuration of Voltage Generating Circuit VG

As shown in FIG. 3, for example, the voltage generating circuit VG (FIG. 1) comprises a plurality of voltage generating units vg1 to vg3. The voltage generating units vg1 to vg3 generate a voltage of a certain magnitude and output the generated voltage via a voltage supply line L_{VG}, in a read operation, a write operation, and an erase operation. For example, the voltage generating unit vg1 outputs a program voltage in a write operation. Moreover, the voltage generating unit vg2 outputs a read pass voltage in a read operation. In addition, the voltage generating unit vg2 outputs a write pass voltage in a write operation. Moreover, the voltage generating unit vg3 outputs a read voltage in a read operation. In addition, the voltage generating unit vg3 outputs a verify voltage in a write operation. The voltage generating units vg1 to vg3 may be a booster circuit such as a charge pump circuit, or may be a step-down circuit such as a regulator, for example. These step-down circuit and booster circuit are each connected to a voltage supply line L_{P}. The voltage supply line L_{P} is applied with a power supply voltage V_{OC} or a ground voltage V_{SS} (FIG. 1). These voltage supply lines L_{P} are connected to a pad electrode P, for example. An operation voltage outputted from the voltage generating circuit VG is appropriately adjusted according to a control signal from the sequencer SQC.

Note that the voltage generating circuit VG exemplified in FIG. 3 includes a configuration for generating multiple types of operation voltages (the program voltage, the read pass voltage, the write pass voltage, the read voltage, and the verify voltage) to be applied to the word line WL. However, the voltage generating circuit VG also includes a configuration for generating multiple types of operation voltages to be applied to the bit line BL, the source line SL, and the select gate lines (SGD, SGS).

### Circuit Configuration of Row Decoder RD

As shown in FIG. 3, for example, the row decoder RD (FIG. 1) comprises the row control circuit RowC, a word line decoder WLD, the driver circuit DRV, and an unillustrated address decoder. As shown in FIG. 4, for example, the row control circuit RowC comprises a plurality of block decoder units blkd and the block decoder BLKD.

The plurality of block decoder units blkd correspond to the plurality of memory blocks BLK in the memory cell array MCA. The block decoder unit blkd comprises a plurality of word line switches WLSW and a plurality of select gate line switches SGSW. The plurality of word line switches WLSW correspond to the plurality of word lines WL in the memory block BLK. The plurality of select gate line switches SGSW correspond to the drain side select gate line SGD and the source side select gate line SGS in the memory block BLK.

The word line switch WLSW and the select gate line switch SGSW are field effect type NMOS transistors, for example. As shown in FIG. 4, for example, a drain electrode of the word line switch WLSW is connected to the word line WL. Drain electrodes of the select gate line switches SGSW are connected to the drain side select gate line SGD and the source side select gate line SGS. Source electrodes of the word line switch WLSW and the select gate line switch SGSW are connected to wirings CGI. The wiring CGI is connected to all of the block decoder units blkd in the row control circuit RowC. Gate electrodes of the word line switch WLSW and the select gate line switch SGSW are connected to signal supply lines BLKSEL. A plurality of the signal supply lines BLKSEL are provided correspondingly to all of the block decoder units blkd. Moreover, the signal supply line BLKSEL is connected to all of the word line switches WLSW and select gate line switches SGSW in the block decoder unit blkd.

The block decoder BLKD (FIG. 4) decodes a block address during a read operation, a write operation, and so on. In a read operation, a write operation, and so on, for example, one signal supply line BLKSEL corresponding to a block address in the address register ADR (FIG. 1) attains an “H” state, and other signal supply lines BLKSEL attain an “L” state. For example, the one signal supply line BLKSEL is applied with a certain drive voltage having a positive magnitude, and the other signal supply lines BLKSEL are applied with the ground voltage V_{SS}, or the like. As a result, all of the word lines WL and select gate lines SG in the one memory block BLK corresponding to this block address are electrically continuous with all of the wirings CGI. Moreover, all of the word lines WL in the other memory blocks BLK attain a floating state.

The word line decoder WLD (FIG. 3) comprises a plurality of word line decode units wld. The plurality of word line decode units wld correspond to the plurality of memory cells MC in the memory string MS. In the example of FIG. 3, the word line decode unit wld comprises two transistors T_{WLS}, T_{WLU}. The transistors T_{WLS}, T_{WLU} are field effect type NMOS transistors, for example. Drain electrodes of the transistors T_{WLS}, T_{WLU} are connected to the wiring CGI. A source electrode of the transistor T_{WLS} is connected to a wiring CGI_{S}. A source electrode of the transistor T_{WLU} is connected to a wiring CGI_{U}. A gate electrode of the transistor T_{WLS} is connected to a signal line WLSEL_{S}. A gate electrode of the transistor T_{WLU} is connected to a signal line WLSEL_{U}. A plurality of the signal lines WLSEL_{S} are provided correspondingly to the transistors T_{WLS} being ones of the pairs of transistors T_{WLS}, T_{WLU}, included in all of the word line decode units wld. A plurality of the signal lines WLSEL_{U} are provided correspondingly to the transistors T_{WLU} being the others of the pairs of transistors T_{WLS}, T_{WLU}, included in all of the word line decode units wld.

In a read operation, a write operation, and so on, for example, the signal line WLSEL_{S} corresponding to one word line decode unit wld corresponding to a page address in the address register ADR (FIG. 1) attains an “H” state, and the signal line WLSEL_{U} corresponding to this signal line WLSEL_{S} attains an “I” state. Moreover, the signal lines WLSEL_{S} corresponding to other word line decode units wld attain an “L” state, and the signal lines WLSEL_{U} corresponding to these signal lines WLSEL_{S} attain an “H” state. Moreover, the wiring CGI_{S} is applied with a voltage corresponding to a selected word line WL. Moreover, the wiring CGI_{U} is applied with a voltage corresponding to an unselected word line WL. As a result, one word line WL corresponding to the above-described page address is applied with the voltage corresponding to the selected word line WL. Moreover, the other word lines WL are applied with the voltage corresponding to the unselected word line WL.

The driver circuit DRV (FIG. 3) comprises six transistors T_{DRV1} to T_{DRV6}, for example. The transistors T_{DRV1} to T_{DRV6} are field effect type NMOS transistors, for example. Drain electrodes of the transistors T_{DRV1} to T_{DRV4} are connected to the wiring CGI_{S}. Drain electrodes of the transistors T_{DRV5}, T_{DRV6} are connected to the wiring CGI_{U}. A source electrode of the transistor T_{DRV1} is connected to an output terminal of the voltage generating unit vg1, via a voltage supply line L_{VG1}. Source electrodes of the transistors T_{DRV2}, T_{DRV5} are connected to an output terminal of the voltage generating unit vg2, via a voltage supply line L_{VG2}. A source electrode of the transistor T_{DRV3} is connected to an output terminal of the voltage generating unit vg3, via a voltage supply line L_{VG3}. Source electrodes of the transistors T_{DRV4}, T_{DRV6} are connected to the pad electrode P, via the voltage supply line L_{P}. Gate electrodes of the transistors T_{DRV1} to T_{DRV6} are respectively connected with signal lines VSEL1 to VSEL6.

In a read operation, a write operation, and so on, for example, one of the plurality of signal lines VSEL1 to VSEL4 corresponding to the wiring CGI_{S} attains an “H” state, and the others attain an “L” state. Moreover, one of the two signal lines VSEL5, VSEL6 corresponding to the wiring CGI_{U} attains an “H” state, and the other attains an “L” state.

The unillustrated address decoder sequentially refers to a row address RA of the address register ADR (FIG. 1) according to a control signal from the sequencer SQC (FIG. 1), for example. The row address RA includes the above-mentioned block address and page address. The address decoder controls voltages of the above-described signal lines BLKSEL, WLSEL_{S}, WLSEL_{U} to an “H” state or an “I” state.

Note that in the example of FIG. 3, the block decoder units blkd are provided one each to each one of the memory blocks BLK in the row decoder RD. However, this configuration can be appropriately changed. For example, the block decoder units blkd may be provided one each to every two or more of the memory blocks BLK in the row decoder RD.

### Circuit Configuration of Sense Amplifier Module SAM

The sense amplifier module SAM (FIG. 1) detects an ON state/OFF state of the memory cell MC, and acquires data indicating a state of this memory cell MC. Such an operation will sometimes be referred to as a sense operation. The sense amplifier module SAM comprises a plurality of sense amplifier units. The plurality of sense amplifier units correspond to a plurality of the bit lines BL. The plurality of sense amplifier units each comprise a sense amplifier circuit and a latch circuit.

### Circuit Configuration of Cache Memory CM

The cache memory CM (FIG. 1) comprises a plurality of latch circuits. The plurality of latch circuits are connected to the latch circuits in the sense amplifier module SAM via a wiring DBUS. Data DAT included in these plurality of latch circuits is sequentially transferred to the sense amplifier module SAM or the input/output control circuit I/O.

Moreover, the cache memory CM is connected with an unillustrated decode circuit and unillustrated switch circuit. The decode circuit decodes a column address CA held in the address register ADR. The switch circuit causes a latch circuit corresponding to the column address CA to be electrically continuous with a bus BUS (FIG. 1), depending on an output signal of the decode circuit.

### Circuit Configuration of Sequencer SQC

The sequencer SQC (FIG. 1) outputs internal control signals to the row decoder RD, the sense amplifier module SAM, and the voltage generating circuit VG, in accordance with command data D_{CMD} held in the command register CMR. In addition, the sequencer SQC appropriately outputs to the status register STR status data D_{ST} indicating a state of the sequencer SQC itself.

Moreover, the sequencer SQC generates a ready/busy signal, and outputs the ready/busy signal to a terminal RY//BY. In a period when the terminal RY//BY is in an “L” state (a busy period), access to the memory die MD is basically prohibited. Moreover, in a period when the terminal RY//BY is in an “H” state (a ready period), access to the memory die MD is permitted.

### Circuit Configuration of Input/Output Control Circuit I/O

The input/output control circuit I/O (FIG. 1) comprises: data signal input/output terminals DQ0 to DQ7; toggle signal input/output terminals DQS, /DQS; a plurality of input circuits; a plurality of output circuits; a shift register; and a buffer circuit. The plurality of input circuits, the plurality of output circuits, the shift register, and the buffer circuit are each connected to terminals applied with a voltage V_{CCQ} and with the ground voltage V_{SS}.

Data inputted via the data signal input/output terminals DQ0 to DQ7 is outputted to the cache memory CM, the address register ADR, or the command register CMR from the buffer circuit, in response to an internal control signal from the logic circuit CTR. Moreover, data outputted via the data signal input/output terminals DQ0 to DQ7 is inputted to the buffer circuit from the cache memory CM or the status register STR, in response to an internal control signal from the logic circuit CTR.

The plurality of input circuits include a comparator connected to any of the data signal input/output terminals DQ0 to DQ7 or to both of the toggle signal input/output terminals DQS, /DQS, for example. The plurality of output circuits include an OCD (Off Chip Driver) circuit connected to any of the data signal input/output terminals DQ0 to DQ7 or to either of the toggle signal input/output terminals DQS, /DQS, for example.

### Circuit Configuration of Logic Circuit CTR

The logic circuit CTR (FIG. 1) receives an external control signal from a controller die CD via external control terminals /CEn, CLE, ALE, /WE, RE, /RE, and outputs an internal control signal to the input/output control circuit I/O depending on this external control signal.

### Structure of Memory Die MD

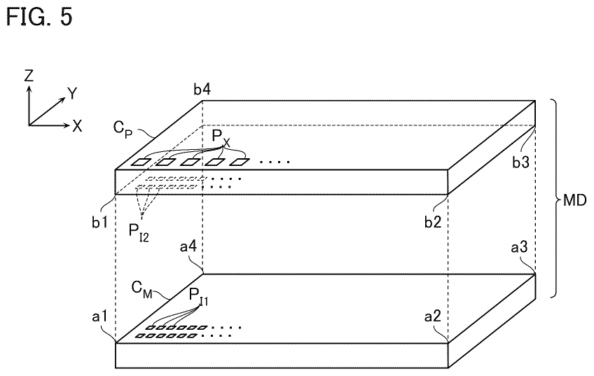

FIG. 5 is a schematic exploded perspective view showing a configuration example of a semiconductor memory device according to the first embodiment. As shown in FIG. 5, the memory die MD comprises: a chip C_{P} on a peripheral circuit PC side; and a chip C_{M} on a memory cell array MCA side.

An upper surface of the chip C_{P} is provided with a plurality of external pad electrodes P_{X} connectable to unillustrated bonding wires. Moreover, a lower surface of the chip C_{P} is provided with a plurality of bonding electrodes P_{I2}. Moreover, an upper surface of the chip C_{M} is provided with a plurality of bonding electrodes P_{I1}. Hereafter, a surface provided with the plurality of bonding electrodes P_{I2}, of the chip C_{P} will be referred to as a front surface of the chip C_{P}, and a surface provided with the plurality of external pad electrodes P_{X}, of the chip C_{P} will be referred to as a back surface of the chip C_{P}. Moreover, a surface provided with the plurality of bonding electrodes P_{I1}, of the chip C_{M} will be referred to as a front surface of the chip C_{M}, and a surface on an opposite side to the front surface, of the chip C_{M} will be referred to as a back surface of the chip C_{M}. In the example illustrated, the back surface of the chip C_{M} is provided below the front surface of the chip C_{M}, and the front surface of the chip C_{P} is provided below the back surface of the chip C_{P}.

The chip C_{P} and the chip C_{M} are disposed so that the front surface of the chip C_{P} and the front surface of the chip C_{M} face each other. Each of the plurality of bonding electrodes P_{I2} is provided correspondingly to the plurality of bonding electrodes P_{I1}, and is disposed at positions enabling them to be bonded to the plurality of bonding electrodes P_{I1}. The bonding electrodes P_{I1} and bonding electrodes P_{I2} function as bonding electrodes for bonding and making electrically continuous the chip C_{M} and chip C_{P}. The plurality of bonding electrodes P_{I2} are connected to the plurality of bonding electrodes P_{I1}.

Note that in the example of FIG. 5, corners b1, b2, b3, b4 of the chip C_{P} respectively correspond to corners a1, a2, a3, a4 of the chip C_{M}.

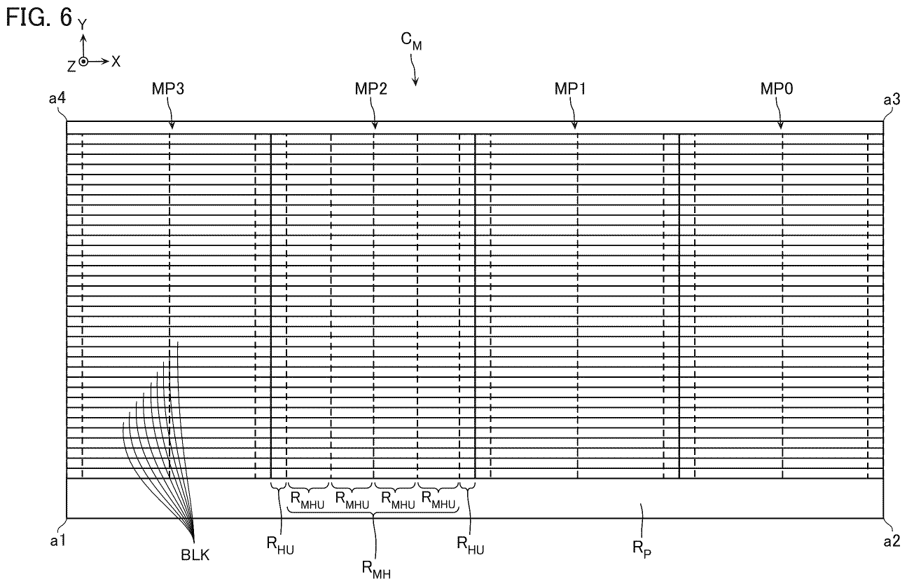

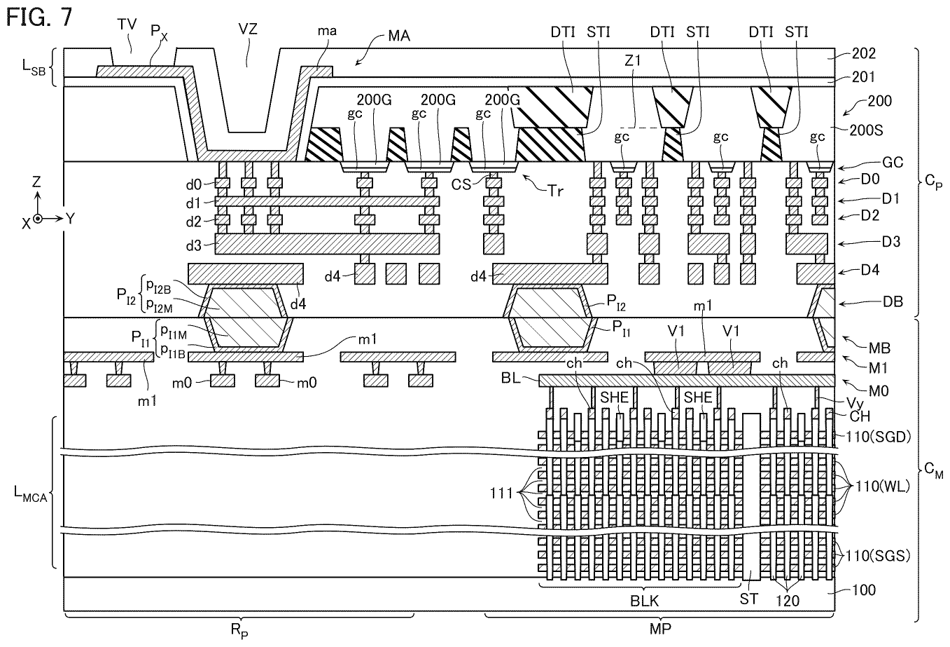

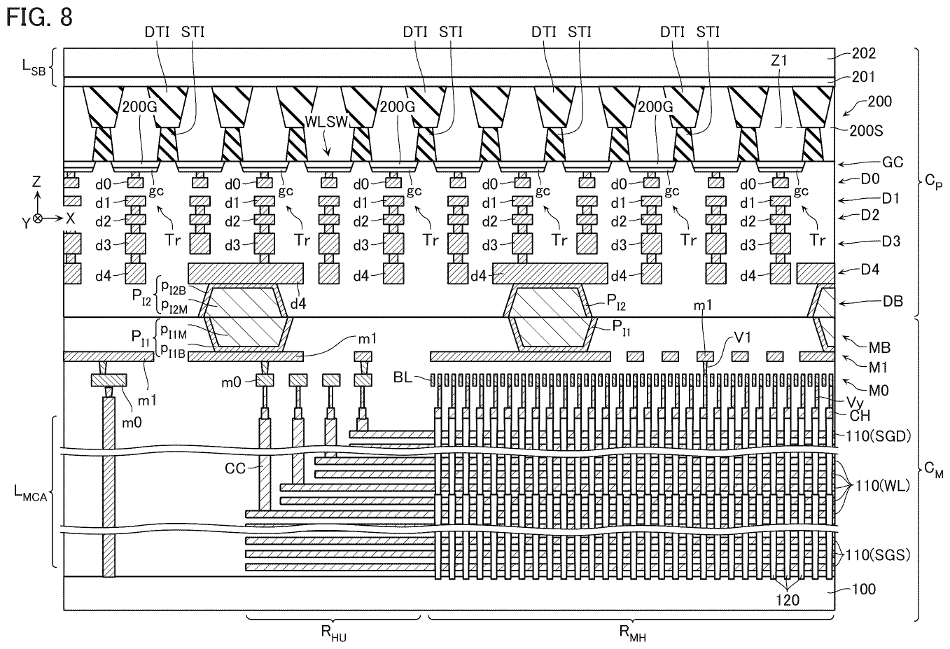

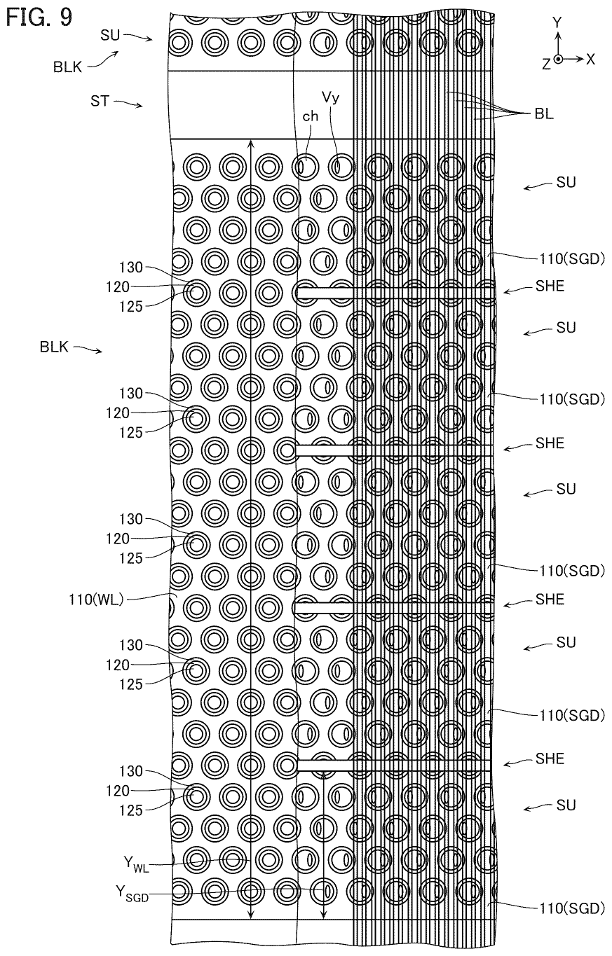

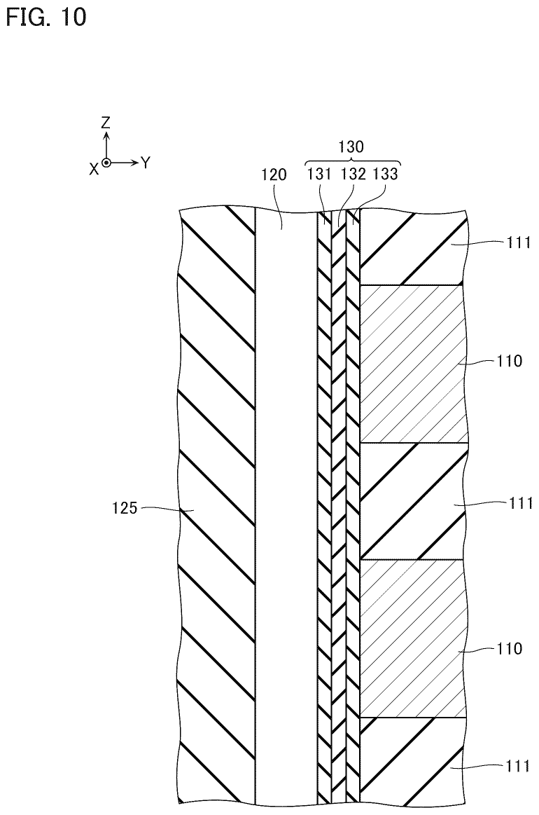

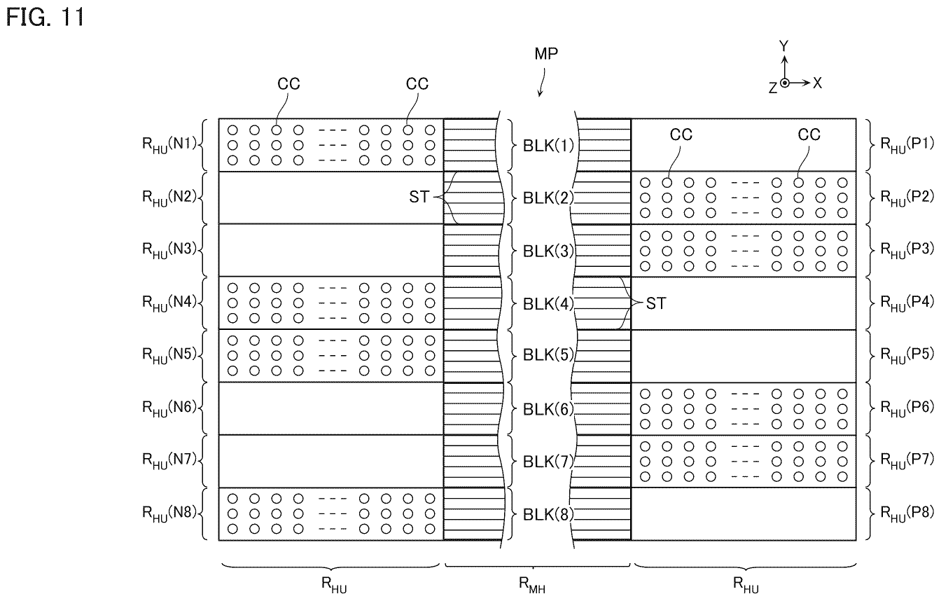

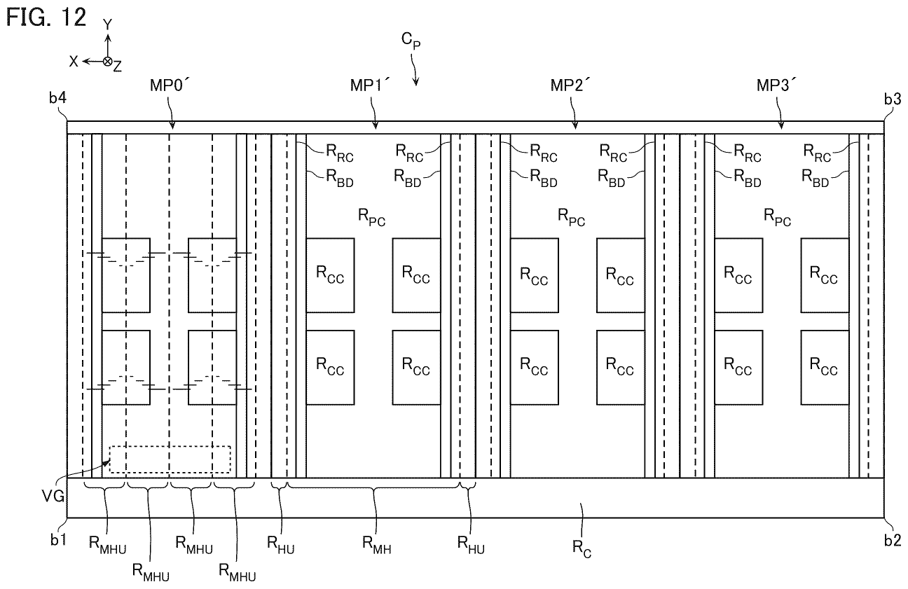

FIG. 6 is a schematic top view showing a configuration example of the chip C_{M}. In FIG. 6, a part of the configuration such as the bonding electrodes P_{I1} is omitted. FIGS. 7 and 8 are schematic cross-sectional views showing a part of configuration of the memory die MD. FIG. 9 is a schematic top view showing a part of the configuration of the chip C_{M}. In FIG. 9, an XY cross section at a position of the word line WL shown in FIG. 7 is shown in a region on a left side, and an XY cross section at a position of the drain side select gate line SGD shown in FIG. 7 is shown in a region on a right side. Note that it is in order to indicate connecting portions of semiconductor columns 120 and the bit lines BL that via contact electrodes ch, Vy and the bit lines BL are also shown in the region on the right side of FIG. 9. The via contact electrodes ch, Vy and the bit lines BL are provided in the region on the left side of FIG. 9 too. FIG. 10 is a schematic cross-sectional view showing a part of the configuration of the chip C_{M}. Although FIG. 10 shows a YZ cross section, a similar structure to in FIG. 10 will be observed, even in the case where a cross section other than a YZ cross section (for example, an XZ cross section) along a central axis of the semiconductor column 120 has been observed. FIG. 11 is a schematic plan view showing a configuration example of a hook-up region R_{HU}. FIG. 12 is a schematic bottom view showing a configuration example of the chip C_{P}. In FIG. 12, a part of the configuration such as the bonding electrodes P_{I2} is omitted.

### Structure of Chip C_{M}

In the example of FIG. 6, the chip C_{M} (FIG. 5) comprises four memory planes MP0 to MP3 arranged in the X-direction. Note that sometimes, the four memory planes MP0 to MP3 will each simply be referred to as a memory plane MP. Moreover, these fours memory planes MP0 to MP3 each comprise a plurality of the memory blocks BLK arranged in the Y-direction. Moreover, in the example of FIG. 6, these four memory planes MP0 to MP3 each comprise: the hook-up regions R_{HU} provided in both end portions in the X-direction; and a memory hole region R_{MH} provided between these hook-up regions R_{HU}. Moreover, in the example of FIG. 6, the memory hole region R_{MH} is divided into four regions R_{MHU} in the X-direction. Widths in the X-direction of these four regions R_{MHU} may be all the same, but need not be all the same. Moreover, the chip C_{M} comprises a peripheral region R_{P} provided further to a side at one end in the Y-direction of the chip C_{M} than the four memory planes MP0 to MP3.

Note that in the example illustrated, the hook-up region R_{HU} is provided in both end portions in the X-direction of the memory plane MP. However, such a configuration is merely an exemplification, and a specific configuration may be appropriately adjusted. For example, the hook-up region R_{HU} may be provided in one end portion in the X-direction of the memory plane MP, rather than in both end portions in the X-direction of the memory plane MP. Moreover, the hook-up region R_{HU} may be provided at a center position or near center position in the X-direction of the memory plane MP.

As shown in FIG. 7, for example, the chip C_{M} comprises: a conductive layer 100; a memory cell array layer L_{MCA} provided above the conductive layer 100; a via contact electrode layer CH provided above the memory cell array layer L_{MCA}; a plurality of wiring layers M0, M1 provided above the via contact electrode layer CH; and a chip bonding electrode layer MB provided above the wiring layers M0, M1.

The conductive layer 100 may include a semiconductor layer of the likes of silicon (Si) implanted with an N-type impurity such as phosphorus (P) or P-type impurity such as boron (B), may include a metal of the likes of tungsten (W), or may include a silicide of the likes of tungsten silicide (WSi), for example.

The conductive layer 100 functions as a part of the source line SL (FIG. 2). Four conductive layers 100 are provided correspondingly to the four memory planes MP0 to MP3 (FIG. 6).

Structure in Memory Hole Region R_{MH} of Memory Cell Array Layer L_{MCA} of Chip C_{M}

As described with reference to FIG. 6, the memory cell array layer L_{MCA} is provided with a plurality of the memory blocks BLK arranged in the Y-direction. As shown in FIG. 7, an inter-block insulating layer ST of the likes of silicon oxide (SiO₂) is provided between two memory blocks BLK adjacent in the Y-direction. A plurality of stacked structures arranged in the Y-direction and each including a plurality of conductive layers 110 arranged in the Z-direction, correspond to the plurality of memory blocks BLK.

As shown in FIG. 7, for example, the memory block BLK comprises: a plurality of the conductive layers 110 arranged in the Z-direction; and a plurality of the semiconductor columns 120 extending in the Z-direction. Moreover, as shown in FIG. 10, a gate insulating film 130 is provided between each of the plurality of conductive layers 110 and plurality of semiconductor columns 120.

The conductive layer 110 (FIG. 7) comprises a substantially plate-like shape extending in the X-direction. The conductive layer 110 may include a stacked film having stacked therein a barrier conductive film of the likes of titanium nitride (TiN) and a metal film of the likes of tungsten (W) or molybdenum (Mo), and so on. Moreover, the conductive layer 110 may include the likes of polycrystalline silicon including an impurity such as phosphorus (P) or boron (B), for example. An inter-layer insulating layer 111 of the likes of silicon oxide (SiO₂) is provided between the plurality of conductive layers 110 arranged in the Z-direction.

One or a plurality of conductive layers 110 located in the lowermost layer, of the plurality of conductive layers 110 (FIG. 7) function as the gate electrodes of the source side select transistors STS (FIG. 2) and as the source side select gate line SGS. These plurality of conductive layers 110 are electrically independent every memory block BLK.

Moreover, the plurality of conductive layers 110 located above these lowermost layer-located conductive layers 110 function as the gate electrodes of the memory cells MC (FIG. 2) and as the word lines WL. These plurality of conductive layers 110 are each electrically independent every memory block BLK.

Moreover, one or a plurality of conductive layers 110 located above these word line WL-functioning conductive layers 110, function as the gate electrodes of the drain side select transistors STD (FIG. 2) and as the drain side select gate line SGD. These plurality of conductive layers 110 are each electrically independent every string unit SU. As shown in FIG. 9, for example, a width Y_{SGD} in the Y-direction of these plurality of conductive layers 110 is smaller than a width Y_{WL} in the Y-direction of the conductive layers 110 functioning as the word lines WL. Moreover, an inter-string unit insulating layer SHE of the likes of silicon oxide (SiO₂) is provided between two conductive layers 110 adjacent in the Y-direction.

As shown in FIG. 9, for example, the semiconductor columns 120 are arranged in a certain pattern in the X-direction and the Y-direction. The respective semiconductor columns 120 function as channel regions of the plurality of memory cells MC and select transistors (STD, STS) included in one memory string MS (FIG. 2). The semiconductor column 120 includes the likes of polycrystalline silicon (Si), for example. The semiconductor column 120 has a substantially cylindrical shape, and has its central portion provided with an insulating layer 125 of the likes of silicon oxide. Outer peripheral surfaces of the semiconductor columns 120 are each surrounded by a plurality of the conductive layers 110, and face these plurality of conductive layers 110.

Moreover, a lower end of the semiconductor column 120 (FIG. 7) is provided with an unillustrated impurity region. This impurity region is connected to the above-described conductive layer 100. This impurity region includes an N-type impurity such as phosphorus (P) or P-type impurity such as boron (B), for example.

Moreover, an upper end of the semiconductor column 120 (FIG. 7) is provided with an unillustrated impurity region. This impurity region is connected to the bit line BL via the via contact electrode ch and the via contact electrode Vy. This impurity region includes an N-type impurity such as phosphorus (P), for example.

As shown in FIG. 9, for example, the gate insulating film 130 has a substantially cylindrical shape covering the outer peripheral surface of the semiconductor column 120. As shown in FIG. 10, for example, the gate insulating film 130 comprises a tunnel insulating film 131, an electric charge accumulating film 132, and a block insulating film 133 that are stacked between the semiconductor column 120 and the conductive layer 110. The tunnel insulating film 131 and the block insulating film 133 include the likes of silicon oxide (SiO₂) or silicon oxynitride (SiON), for example. The electric charge accumulating film 132 includes a film capable of accumulating a charge, of the likes of silicon nitride (SiN), for example. The tunnel insulating film 131, the electric charge accumulating film 132, and the block insulating film 133 have substantially cylindrical shapes, and extend in the Z-direction along the outer peripheral surface of the semiconductor column 120 excluding a contact portion of the semiconductor column 120 and the conductive layer 100.

Note that FIG. 10 has shown an example where the gate insulating film 130 comprises the electric charge accumulating film 132 of the likes of silicon nitride. However, the gate insulating film 130 may comprise a floating gate of the likes of polycrystalline silicon including an N-type or P-type impurity, for example.

Structure in Hook-Up Region R_{HU} of Memory Cell Array Layer L_{MCA} of Chip C_{M}

As shown in FIG. 8, the hook-up region R_{HU} is provided with a plurality of via contact electrodes CC (contacts). These plurality of via contact electrodes CC each extend in the Z-direction and are connected at their lower ends to the conductive layers 110 (WL, SGD, SGS).

As shown in FIG. 11, the hook-up regions R_{HU} are provided on a negative side in the X-direction and a positive side in the X-direction of the memory plane MP, and the memory hole region R_{MH} is provided between the two hook-up regions R_{HU}. In the memory hole region R_{MH}, first through eighth memory blocks counting from a positive side in the Y-direction are assumed to be memory blocks BLK (1) to BLK (8). The hook-up region R_{HU} on a negative side in the X-direction is divided into hook-up regions R_{HU} (N1) to R_{HU} (N8) correspondingly to the memory blocks BLK (1) to BLK (8). Moreover, the hook-up region R_{HU} on the positive side in the X-direction is divided into hook-up regions R_{HU} (P1) to R_{HU} (P8) correspondingly to the memory blocks BLK (1) to BLK (8).

In the hook-up regions R_{HU} (N1), R_{HU} (N4), R_{HU} (N5), R_{HU} (N8), R_{HU} (P2), R_{HU} (P3), R_{HU} (P6), R_{HU} (P7), a plurality of columns of three via contact electrodes CC arranged in the Y-direction, are arranged in the X-direction.

The plurality of via contact electrodes CC of the hook-up region R_{HU} (N1) are connected to the conductive layers 110 of each layer in the memory block BLK (1). The plurality of via contact electrodes CC of the hook-up region R_{HU} (P2) are connected to the conductive layers 110 of each layer in the memory block BLK (2). The plurality of via contact electrodes CC of the hook-up region R_{HU} (P3) are connected to the conductive layers 110 of each layer in the memory block BLK (3). The plurality of via contact electrodes CC of the hook-up region R_{HU} (N4) are connected to the conductive layers 110 of each layer in the memory block BLK (4). The plurality of via contact electrodes CC of the hook-up region R_{HU} (N5) are connected to the conductive layers 110 of each layer in the memory block BLK (5). The plurality of via contact electrodes CC of the hook-up region R_{HU} (P6) are connected to the conductive layers 110 of each layer in the memory block BLK (6). The plurality of via contact electrodes CC of the hook-up region R_{HU} (P7) are connected to the conductive layers 110 of each layer in the memory block BLK (7). The plurality of via contact electrodes CC of the hook-up region R_{HU} (N8) are connected to the conductive layers 110 of each layer in the memory block BLK (8).

### Structure of Via Contact Electrode Layer CH

The plurality of via contact electrodes ch included in the via contact electrode layer CH (FIG. 7) are electrically connected to at least one of the configuration in the memory cell array layer L_{MCA} and the configuration in the chip C_{P}, for example.

The via contact electrode layer CH includes a plurality of the via contact electrodes ch. These plurality of via contact electrodes ch may include for example a stacked film having stacked therein a barrier conductive film of the likes of titanium nitride (TiN) and a metal film of the likes of tungsten (W), and so on. The via contact electrodes ch are provided correspondingly to the plurality of semiconductor columns 120, and are connected to the upper ends of the plurality of semiconductor columns 120.

### Structure of Wiring Layers M0, M1 of Chip C_{M}

A plurality of wirings included in the wiring layers M0, M1 (FIG. 7) are electrically connected to at least one of the configuration in the memory cell array layer L_{MCA} and the configuration in the chip C_{P}, for example.

As shown in FIG. 7, for example, the wiring layer M0 includes a plurality of wirings m0. These plurality of wirings m0 may include for example the likes of a stacked film having stacked therein: a barrier conductive film of the likes of titanium nitride (TiN), tantalum nitride (TaN), or a stacked film of tantalum nitride (TaN) and tantalum (Ta); and a metal film of the likes of copper (Cu). Note that parts of the plurality of wirings m0 function as the bit lines BL. As shown in FIG. 9, for example, the bit lines BL are arranged in the X-direction and extend in the Y-direction.

As shown in FIG. 7, for example, the wiring layer M1 includes a plurality of wirings m1. These plurality of wirings ml may include for example a stacked film having stacked therein a barrier conductive film of the likes of titanium nitride (TiN) and a metal film of the likes of tungsten (W), and so on.

### Structure of Chip Bonding Electrode Layer MB

A plurality of configurations included in the chip bonding electrode layer MB (refer to FIGS. 7 and 8) are electrically connected to at least one of the configuration in the memory cell array layer L_{MCA} and the configuration in the chip C_{P}, for example.

The chip bonding electrode layer MB includes a plurality of the bonding electrodes P_{I1} (bonding pads). These plurality of bonding electrodes P_{I1} may include for example the likes of a stacked film having stacked therein: a barrier conductive film p_{I1B} of the likes of titanium nitride (TiN), tantalum nitride (TaN), or a stacked film of tantalum nitride (TaN) and tantalum (Ta); and a metal film p_{I1M} of the likes of copper (Cu).

### Structure of Chip C_{P}

As shown in the example of FIG. 12, the chip C_{P} comprises four regions MP0′ to MP3′ arranged in the X-direction overlapping the memory planes MP0 to MP3. Both end portions in the X-direction, of these four regions MP0′ to MP3′ are each provided with a row control circuit region R_{RC}. Moreover, in-between these two row control circuit regions R_{RC}, there are provided two block decoder regions R_{BD} arranged in the X-direction. Moreover, in-between these two block decoder regions R_{BD}, there is provided a peripheral circuit region R_{PC}. The peripheral circuit region R_{PC} is provided with four column control circuit regions R_{CC} arranged in the X-direction and the Y-direction. In the region MP0′, one end portion in the Y-direction, of the peripheral circuit region R_{PC} is provided with the voltage generating circuit VG. Moreover, other regions in the peripheral circuit region R_{PC} also have circuits disposed therein, although illustration of this is omitted. Moreover, a region of the chip C_{P} facing the peripheral region R_{P} (FIG. 6) of the chip C_{M} is provided with a circuit region R_{C}.

The row control circuit region R_{RC} is provided with a plurality of the block decoder units blkd described with reference to FIGS. 3 and 4. That is, the row control circuit region R_{RC} is provided with the plurality of word line switches WLSW and plurality of select gate line switches SGSW configuring the plurality of block decoder units blkd. The block decoder region R_{BD} is provided with the block decoder BLKD described with reference to FIG. 4. The column control circuit region R_{CC} is provided with the sense amplifier module SAM described with reference to FIG. 1.

The circuit region R_{C} is provided with an unillustrated input/output circuit. This input/output circuit is electrically connected to the external pad electrode P_{X} via later-mentioned wiring layers D0, D1, and so on. Moreover, this input/output circuit includes: an object circuit according to the first embodiment; and a control circuit that adjusts electrical characteristics of this object circuit. The object circuit according to the first embodiment is a transistor (a foot switch FSW) connected to a part of a plurality of transistors (for example, a CMOS circuit). The control circuit enables a voltage applied to a body of the later-mentioned transistor being the foot switch FSW, for example, to be controlled independently of a voltage applied to a body of the a part of the plurality of transistors being the CMOS circuit, for example. The control circuit controls electrical characteristics (more specifically, a threshold voltage) of the transistor being the foot switch FSW by controlling the voltage applied to the body of the transistor being the foot switch FSW.

Moreover, in FIG. 12, a region overlapping the hook-up region R_{HU} (FIG. 6) viewed from the Z-direction is shown by a dotted line. In the example of FIG. 12, a part of the row control circuit region R_{RC} is provided in the region overlapping the hook-up region R_{HU} (FIG. 6) viewed from the Z-direction. Moreover, a part of the row control circuit region R_{RC} is provided in a region overlapping the memory hole region R_{MH} (FIG. 6) viewed from the Z-direction. Moreover, in the example of FIG. 12, a width in the X-direction of the row control circuit region R_{RC} is larger than a width in the X-direction of the hook-up region R_{HU} (FIG. 6). In this way, the plurality of word line switches WLSW and select gate line switches SGSW of the row control circuit region R_{RC} are provided at positions overlapping parts of the hook-up region R_{HU} and memory hole region R_{MH} viewed from the Z-direction.

Moreover, in the example of FIG. 12, a center position in the X-direction of the column control circuit region R_{CC} coincides with a boundary of first and second regions R_{MHU} counting from the positive side in the X-direction or boundary of third and fourth regions R_{MHU} counting from the positive side in the X-direction. Note that the center position in the X-direction of the column control circuit region R_{CC} need not coincide with the boundary of the first and second regions R_{MHU} counting from the positive side in the X-direction or boundary of the third and fourth regions R_{MHU} counting from the positive side in the X-direction.

Moreover, as shown in FIG. 7, for example, the chip C_{P} comprises: a substrate layer L_{SB}; a semiconductor substrate 200 provided below the substrate layer L_{SB}; an electrode layer GC provided below the semiconductor substrate 200; the wiring layers D0, D1 and wiring layers D2, D3, D4 provided below the electrode layer GC; and a chip bonding electrode layer DB provided below the wiring layers D0, D1, D2, D3, D4.

Structure of Substrate Layer L_{SB} of Chip C_{P}

As shown in FIG. 7, for example, the substrate layer L_{SB} comprises: an insulating layer 201 provided on an upper surface of the semiconductor substrate 200; a back surface wiring layer MA provided on a bottom surface and inner peripheral surface of an opening VZ, and in a peripheral portion of the opening VZ; and an insulating layer 202 provided on an upper surface of the back surface wiring layer MA and upper surface of the insulating layer 201.

The insulating layer 201 includes the likes of silicon oxide (SiO₂), for example.

The back surface wiring layer MA includes a plurality of wirings ma. These plurality of wirings ma may include the likes of aluminum (Al), for example.

Moreover, at least a part of the plurality of wirings ma functions as the external pad electrode P_{X}. This wiring ma is provided in the peripheral region R_{P}. This wiring ma is electrically connected to configurations in the wiring layers D0 to D4 at the bottom surface of the opening VZ. Moreover, a part of the wiring ma is exposed to outside of the memory die MD via an opening TV provided in the insulating layer 202.

The insulating layer 202 is a passivation layer consisting of an insulating material such as a polyimide, for example.

### Structure of Semiconductor Substrate 200 of Chip C_{P}

The semiconductor substrate 200 includes P-type silicon (Si) that includes a P-type impurity such as boron (B), for example. Moreover, the semiconductor substrate 200 comprises a semiconductor substrate region 200S, an insulating member STI, and an insulating member DTI, for example. The semiconductor substrate region 200S functions as parts of a plurality of transistors Tr and plurality of capacitors, and so on, configuring the peripheral circuit PC. Note that a part of the plurality of transistors Tr functions as the object circuit, as the CMOS circuit connected to the object circuit, as the word line switches WLSW, and as the select gate line switches SGSW.

The insulating member STI includes the likes of silicon oxide (SiO₂), for example. The insulating member STI is provided between two transistors Tr adjacent in the X-direction or the Y-direction. The insulating member STI extends in the Z-direction from a front surface (a lower surface) of the semiconductor substrate 200 to a position Z1 between the front surface and a back surface of the semiconductor substrate 200.

As will be mentioned later, the insulating member STI includes a portion extending in the X-direction or the Y-direction. A side surface in the Y-direction of the portion extending in the X-direction of the insulating member STI has a tapered shape in a YZ cross section. That is, a width in the Y-direction at a lower end (a width in the Y-direction at a height position of the lower surface of the semiconductor substrate 200) of this portion is larger than a width in the Y-direction at an upper end (a width in the Y-direction at the position Z1) of this portion. Similarly, a side surface in the X-direction of the portion extending in the Y-direction of the insulating member STI has a tapered shape in an XZ cross section. That is, a width in the X-direction at a lower end (a width in the X-direction at the height position of the lower surface of the semiconductor substrate 200) of this portion is larger than a width in the X-direction at an upper end (a width in the X-direction at the position Z1) of this portion.

The insulating member DTI includes the likes of silicon oxide (SiO₂), for example. The insulating member DTI is provided at a position overlapping the insulating member STI viewed from the Z-direction, between two transistors Tr adjacent in the X-direction or the Y-direction. The insulating member DTI is basically provided at a position overlapping the insulating member STI, viewed from the Z-direction. However, a part of the insulating members STI is provided at a position not overlapping the insulating member DTI, viewed from the Z-direction.

The insulating member DTI extends in the Z-direction from the back surface (an upper surface) of the semiconductor substrate 200 to the position Z1. As will be mentioned later, the insulating member DTI includes a portion extending in the X-direction or the Y-direction. A side surface in the Y-direction of the portion extending in the X-direction of the insulating member DTI has a tapered shape in a YZ cross section. That is, a width in the Y-direction at an upper end (a width in the Y-direction at a height position of the upper surface of the semiconductor substrate 200) of this portion is larger than a width in the Y-direction at a lower end (a width in the Y-direction at the position Z1) of this portion. Similarly, a side surface in the X-direction of the portion extending in the Y-direction of the insulating member DTI has a tapered shape in an XZ cross section. That is, a width in the X-direction at an upper end (a width in the X-direction at the height position of the upper surface of the semiconductor substrate 200) of this portion is larger than a width in the X-direction at a lower end (a width in the X-direction at the position Z1) of this portion.

A width in the Y-direction at the upper end (a width in the Y-direction at the height position of the upper surface of the semiconductor substrate 200) of the portion extending in the X-direction, of the insulating member DTI is larger than a width in the Y-direction at the lower end (a width in the Y-direction at the height position of the lower surface of the semiconductor substrate 200) of the portion extending in the X-direction, of the insulating member STI. Moreover, a width in the Y-direction at the lower end (a width in the Y-direction at the position Z1) of the portion extending in the X-direction, of the insulating member DTI is larger than a width in the Y-direction at the upper end (a width in the Y-direction at the position Z1) of the portion extending in the X-direction, of the insulating member STI.

Similarly, a width in the X-direction at the upper end (a width in the X-direction at the height position of the upper surface of the semiconductor substrate 200) of the portion extending in the Y-direction, of the insulating member DTI is larger than a width in the X-direction at the lower end (a width in the X-direction at the height position of the lower surface of the semiconductor substrate 200) of the portion extending in the Y-direction, of the insulating member STI. Moreover, a width in the X-direction at the lower end (a width in the X-direction at the position Z1) of the portion extending in the Y-direction, of the insulating member DTI is larger than a width in the X-direction at the upper end (a width in the X-direction at the position Z1) of the portion extending in the Y-direction, of the insulating member STI.

### Structure of Electrode Layer GC of Chip C_{P}

As shown in FIG. 7, for example, the electrode layer GC is provided on the lower surface of the semiconductor substrate 200 via an insulating layer 200G. The electrode layer GC includes a plurality of electrodes gc that face the front surface of the semiconductor substrate 200. Moreover, each of the regions of the semiconductor substrate 200 and the plurality of electrodes gc included in the electrode layer GC is connected to via contact electrodes (contacts) CS.

The semiconductor substrate region 200S functions as channel regions of the plurality of transistors Tr and as one electrodes of the plurality of capacitors, and so on, configuring the peripheral circuit PC.

The respective plurality of electrodes gc included in the electrode layer GC function as gate electrodes of the plurality of transistors Tr, as the other electrodes of the plurality of capacitors, and so on, configuring the peripheral circuit PC.

As shown in FIG. 7, for example, the via contact electrode CS extends in the Z-direction, and is connected at its upper end to a lower surface of the semiconductor substrate region 200S of the semiconductor substrate 200 or to a lower surface of the electrode gc. A connecting portion of the via contact electrode CS and the semiconductor substrate region 200S of the semiconductor substrate 200 is provided with an impurity region including an N-type impurity or P-type impurity. The via contact electrode CS may include for example a stacked film having stacked therein a barrier conductive film of the likes of titanium nitride (TiN) and a metal film of the likes of tungsten (W), and so on.

### Structure of Wiring Layers D0, D1, D2, D3, D4 of Chip C_{P}

As shown in FIG. 8, for example, a plurality of wirings included in the wiring layers D0, D1, D2, D3, D4 are electrically connected to at least one of configurations in the memory cell array layer L_{MCA} and configurations in the chip C_{P}, for example.

The wiring layers D0, D1, D2 respectively include pluralities of wirings d0, d1, d2. These pluralities of wirings d0, d1, d2 may include for example a stacked film having stacked therein a barrier conductive film of the likes of titanium nitride (TiN) and a metal film of the likes of tungsten (W), and so on.

The wiring layers D3, D4 respectively include pluralities of wirings d3, d4. These pluralities of wirings d3, d4 may include for example the likes of a stacked film having stacked therein: a barrier conductive film of the likes of titanium nitride (TiN), tantalum nitride (TaN), or a stacked film of tantalum nitride (TaN) and tantalum (Ta); and a metal film of the likes of copper (Cu).

### Structure of Chip Bonding Electrode Layer DB

A plurality of wirings included in the chip bonding electrode layer DB are electrically connected to at least one of configurations in the memory cell array layer L_{MCA} and configurations in the chip C_{P}, for example.

The chip bonding electrode layer DB includes a plurality of the bonding electrodes P_{I2}. These plurality of bonding electrodes P_{I2} may include for example the likes of a stacked film having stacked therein: a barrier conductive film p_{I2B} of the likes of titanium nitride (TiN), tantalum nitride (TaN), or a stacked film of tantalum nitride (TaN) and tantalum (Ta); and a metal film p_{I2M} of the likes of copper (Cu).

Note that when the metal films p_{I1M}, p_{I2M} of the likes of copper (Cu) are employed in the bonding electrode P_{I1} and bonding electrode P_{I2}, the metal film p_{I1M} and the metal film p_{I2M} become one metal film, so that identification of their boundary with each other becomes difficult. However, due to distortion of shape where the bonding electrode P_{I1} and bonding electrode P_{I2} have been bonded resulting from positional shift of bonding, and due to positional shift (generation of discontinuous places in side surfaces) of the barrier conductive films p_{I1B}, p_{I2B}, bonding structure can be identified. Moreover, when the bonding electrode P_{I1} and bonding electrode P_{I2} are formed by a damascene method, their respective side surfaces will have a tapered shape. Therefore, shape of a cross section along the Z-direction in a portion where the bonding electrode P_{I1} and bonding electrode P_{I2} have been bonded will be non-rectangular due to side walls being non-linearly shaped. Moreover, when the bonding electrode P_{I1} and bonding electrode P_{I2} are bonded, there will be a structure where each of a bottom surface, side surface, and upper surface of the Cu forming them will be covered by a barrier metal. In contrast, in a general wiring layer employing Cu, the upper surface of the Cu is provided with an insulating layer (of the likes of SiN or SiCN) functioning to prevent oxidation of the Cu, and is not provided with a barrier metal. Therefore, distinction from a general wiring layer is possible, even when positional shift of bonding has not occurred.

### Arrangement Pattern of Word Line Switches WLSW, Select Gate Line Switches SGSW, and Insulating Members STI in Row Control Circuit Region R_{RC}

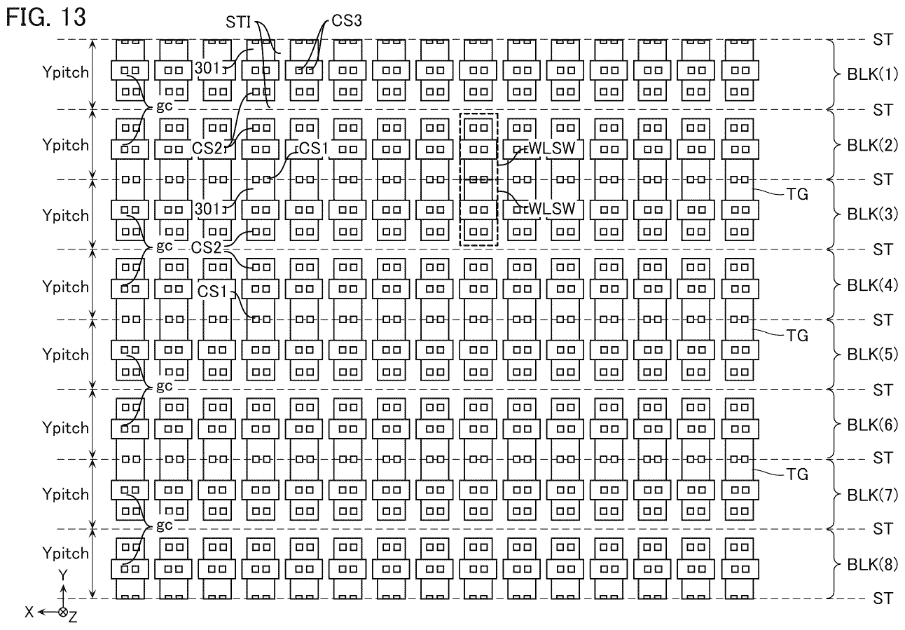

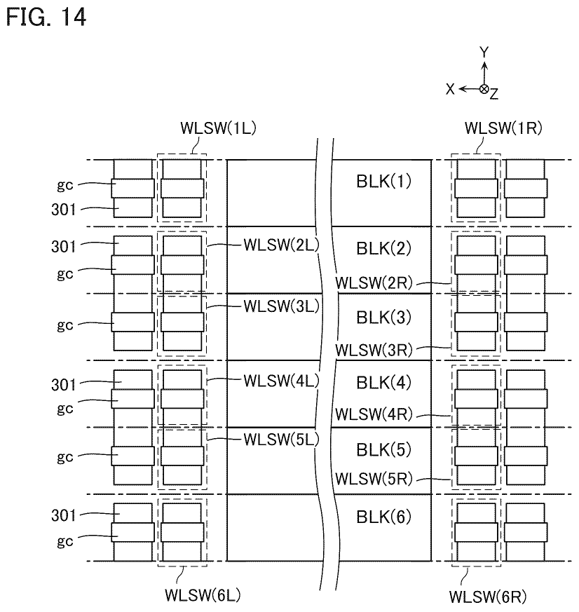

Next, an arrangement pattern of the word line switches WLSW, select gate line switches SGSW, and insulating members STI in the row control circuit region R_{RC} will be described with reference to FIGS. 13 and 14. FIGS. 13 and 14 are schematic bottom views exemplifying the arrangement pattern of the word line switches WLSW, select gate line switches SGSW, and insulating members STI in the semiconductor substrate 200 in the row control circuit region R_{RC}. Note that in FIGS. 13 and 14, dotted lines indicating boundaries of the memory blocks BLK are shown in order to explain a correspondence relationship of the word line switches WLSW and the memory blocks BLK.

FIG. 13 shows two word line switches WLSW (transistors) having a common source region. Hereafter, such a pair of word line switches WLSW (transistors) will be referred to as a “transistor group TG”.

As shown in FIG. 13, the transistor group TG comprises a semiconductor region (diffusion region) 301 extending in the Y-direction. The semiconductor region 301 is a part of the lower surface of the semiconductor substrate region 200S described with reference to FIG. 7, and so on. The semiconductor regions 301 are arranged in both the X-direction and the Y-direction. The insulating member STI is formed in a periphery of the semiconductor region 301. That is, in-between two semiconductor regions 301 adjacent in the X-direction, there is provided the above-mentioned portion extending in the Y-direction, of the insulating member STI. Moreover, in-between two semiconductor regions 301 adjacent in the Y-direction, there is provided the above-mentioned portion extending in the X-direction, of the insulating member STI. Moreover, both end portions in the Y-direction of the semiconductor region 301 are each provided with a via contact electrode CS2 functioning as a drain terminal of the word line switch WLSW. Moreover, in-between these via contact electrodes CS2, there is provided a via contact electrode CS1 functioning as a common source terminal of the two word line switches WLSW. Moreover, in-between each of the via contact electrodes CS2 functioning as the drain terminals and the via contact electrode CS1 functioning as the source terminal, there is provided the electrode gc. The electrode gc is provided with a via contact electrode CS3.

As shown in FIG. 13, a position of an intermediate line equidistant from an end portion on a negative side in the Y-direction of the semiconductor region 301 provided on a positive side in the Y-direction, of a pair of the semiconductor regions 301 arranged in the Y-direction and an end portion on a positive side in the Y-direction of the semiconductor region 301 provided on a negative side in the Y-direction, of the pair of semiconductor regions 301 arranged in the Y-direction coincides with a position of the inter-block insulating layer ST (FIGS. 7 and 9), viewed from the Z-direction. Moreover, a position of a center line in the Y-direction of the semiconductor region 301 also coincides with a position of the inter-block insulating layer ST (FIGS. 7 and 9), viewed from the Z-direction. Spacing of the inter-block insulating layers ST arranged in the Y-direction is the same as pitch in the Y-direction of the word line switches WLSW (Ypitch in FIG. 13). That is, in the present embodiment, pitch in the Y-direction of the word line switches WLSW is the same as pitch in the Y-direction of the memory blocks BLK. Pitches in the Y-direction of the word line switches WLSW and memory blocks BLK being the same will sometimes be notated as 1Tr/1BLK.

Note that although FIG. 13 shows structure of the word line switch WLSW, structure of the select gate line switch SGSW may also be configured similarly to structure of the word line switch WLSW.

In FIG. 14, the word line switch WLSW provided at a position overlapping the memory block BLK (1) viewed from the Z-direction and provided in the row control circuit region R_{RC} on a negative side in the X-direction, of the plurality of word line switches WLSW is shown as a word line switch WLSW (1L). Similarly, the word line switches WLSW provided at positions overlapping the memory blocks BLK (2) to BLK (6) viewed from the Z-direction and provided in the row control circuit region R_{RC} on a negative side in the X-direction, of the plurality of word line switches WLSW are shown as word line switches WLSW (2L) to WLSW (6L).

Moreover, in FIG. 14, the word line switch WLSW provided at a position overlapping the memory block BLK (1) viewed from the Z-direction and provided in the row control circuit region R_{RC} on the positive side in the X-direction, of the plurality of word line switches WLSW is shown as a word line switch WLSW (1R). Similarly, the word line switches WLSW provided at positions overlapping the memory blocks BLK (2) to BLK (6) viewed from the Z-direction and provided in the row control circuit region R_{RC} on the positive side in the X-direction, of the plurality of word line switches WLSW are shown as word line switches WLSW (2R) to WLSW (6R).

As described with reference to FIG. 11, the plurality of via contact electrodes CC connected to the plurality of conductive layers 110 in the memory block BLK (1) are provided on a negative side in the X-direction, with respect to the memory hole region R_{MH}. Now, these plurality of via contact electrodes CC are electrically connected to the via contact electrodes CS2 of the plurality of word line switches WLSW (1L) arranged in the X-direction and plurality of word line switches WLSW (2L) arranged in the X-direction, via the bonding electrodes P_{I1}, P_{I2} and wiring layers D0 to D4.

Similarly, the plurality of via contact electrodes CC connected to the plurality of conductive layers 110 in the memory block BLK (2) (refer to FIG. 11) are electrically connected to the via contact electrodes CS2 of the plurality of word line switches WLSW (1R) arranged in the X-direction and plurality of word line switches WLSW (2R) arranged in the X-direction, via the bonding electrodes P_{I1}, P_{I2} and wiring layers D0 to D4.

Similarly, the plurality of via contact electrodes CC connected to the plurality of conductive layers 110 in the memory block BLK (3) (refer to FIG. 11) are electrically connected to the via contact electrodes CS2 of the plurality of word line switches WLSW (3R) arranged in the X-direction and plurality of word line switches WLSW (4R) arranged in the X-direction, via the bonding electrodes P_{I1}, P_{I2} and wiring layers D0 to D4.

Similarly, the plurality of via contact electrodes CC connected to the plurality of conductive layers 110 in the memory block BLK (4) (refer to FIG. 11) are electrically connected to the via contact electrodes CS2 of the plurality of word line switches WLSW (3L) arranged in the X-direction and plurality of word line switches WLSW (4L) arranged in the X-direction, via the bonding electrodes P_{I1}, P_{I2} and wiring layers D0 to D4.

In this way, pairs of word line switches WLSW spanning a width of a pair of the memory blocks BLK are connected to the conductive layers 110 (word lines WL) of the same memory block BLK. Note that the same applies also to connection of the select gate lines SG and select gate line switches SGSW.

### Structure of Part of Plurality of Transistors and Object Circuit Provided in Circuit Region R_{C}

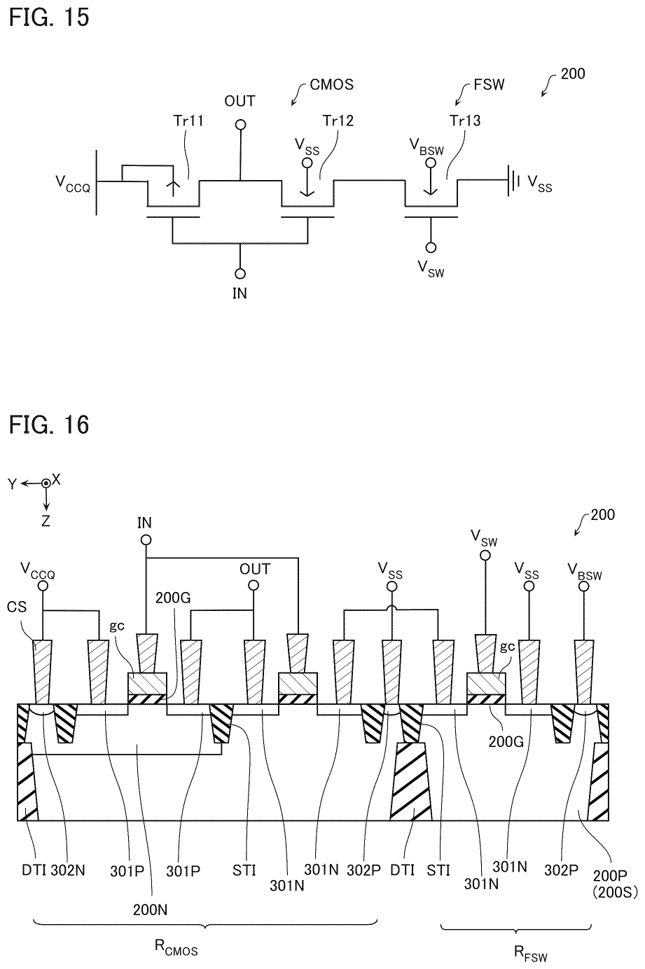

FIG. 15 is a circuit diagram exemplifying a circuit of a part of the plurality of transistors in the semiconductor substrate 200 and the object circuit connected to this circuit, according to the first embodiment. In FIG. 15, the voltage V_{CCQ} is the power supply voltage, and the voltage V_{SS} is the ground voltage. FIG. 16 is a schematic cross-sectional view showing a connection relationship of configurations of the part of the plurality of transistors in the semiconductor substrate 200 and the object circuit connected to these transistors according to the first embodiment.

FIG. 15 exemplifies configurations of the part of the plurality of transistors in the semiconductor substrate 200 and the object circuit connected to these transistors, in the circuit region R_{C} (FIG. 12). For example, FIG. 15 shows: a P-channel MOS transistor Tr11 and an N-channel MOS transistor Tr12 configuring the CMOS circuit provided in the circuit region R_{C} (FIG. 12), as the part of the plurality of transistors in the semiconductor substrate 200; and an N-channel MOS transistor Tr13 (the foot switch FSW) being the object circuit according to the first embodiment, connected to this CMOS circuit.

The P-channel MOS transistor Tr11 has its source electrode and its substrate electrode applied with the voltage V_{CCQ}, has its drain electrode connected to an output terminal OUT of the CMOS circuit, and has its gate electrode connected to an input terminal IN of the CMOS circuit. The N-channel MOS transistor Tr12 has its source electrode connected to a drain electrode of the N-channel MOS transistor Tr13, has its drain electrode connected to the output terminal OUT of the CMOS circuit, has its gate electrode connected to the input terminal IN of the CMOS circuit, and has its substrate electrode applied with the voltage V_{SS}. In the CMOS circuit, for example, the P-channel MOS transistor Tr11 functions as a pull-up side transistor, and the N-channel MOS transistor Tr12 functions as a pull-down side transistor. The N-channel MOS transistor Tr13 has its source electrode applied with the voltage V_{SS}, and has its gate electrode applied with a voltage V_{SW}. Moreover, the substrate electrode of the N-channel MOS transistor Tr12 and a substrate electrode of the N-channel MOS transistor Tr13 are able to be applied with different voltages.

As shown in FIG. 16, the circuit region R_{C} comprises: a region R_{FSW} which is a region of the semiconductor substrate 200 (the semiconductor substrate region 200S) surrounded by the insulating members DTI and the insulating members STI, and has the foot switch FSW formed therein; and a region R_{CMOS} which is a region of the semiconductor substrate 200 (the semiconductor substrate region 200S) surrounded by the insulating members DTI and the insulating members STI, and has the CMOS circuit formed therein.

As mentioned above, in the circuit region R_{C}, the insulating member DTI is provided at positions overlapping a part of the insulating members STI viewed from the Z-direction. As a result, the semiconductor substrate region 200S is divided into a plurality of regions, via the insulating member DTI and the insulating member STI. That is, as shown in FIG. 16, the region R_{FSW} and the region R_{CMOS} which are adjacent in the Y-direction are electrically isolated by the insulating member STI and the insulating member DTI. In the present embodiment, fellow substrate regions of the foot switch FSW being the object circuit and the CMOS circuit being the part of the plurality of transistors and being adjacent in the Y-direction to the foot switch FSW, are electrically isolated by the insulating member STI and the insulating member DTI.

As mentioned above, the semiconductor substrate region 200S is a region including P-type silicon (Si) that includes a P-type impurity such as boron (B), for example. In the circuit region R_{C}, as shown in FIG. 16, the semiconductor substrate region 200S functions as a P-type well region 200P and as a channel region of the N-channel MOS transistor Tr13 (FIG. 15).

The semiconductor substrate region 200S in the region R_{FSW} has formed therein semiconductor regions 301N (diffusion regions) that configure a source region and a drain region of the N-channel MOS transistor Tr13 (FIG. 15). These semiconductor regions 301N are connected to the via contact electrodes (contacts) CS functioning as the source electrode and the drain electrode of the N-channel MOS transistor Tr13.

Moreover, as shown in FIG. 16, the N-channel MOS transistor Tr13 (FIG. 15) comprises: the insulating layer 200G (gate insulating layer) provided on a surface of the semiconductor region 301N; and the electrode gc (gate electrode) provided on a surface of the insulating layer 200G. The electrode gc is connected to the via contact electrode (contact) CS functioning as the gate electrode of the N-channel MOS transistor Tr13.

A body contact region 302P in the region R_{FSW} is provided in a part of a surface of the semiconductor substrate region 200S. A surface of the body contact region 302P is provided with the via contact electrode CS (contact) functioning as the substrate electrode of the N-channel MOS transistor Tr13. The body contact region 302P is an impurity region for contact, and includes a P-type impurity of the likes of boron (B), that is, an impurity of the same conductive type as the semiconductor substrate region 200S. Impurity concentration of the body contact region 302P is higher than impurity concentration of the semiconductor substrate region 200S. Note that the body contact region 302P in the region R_{CMOS} is configured similarly to the body contact region 302P in the region R_{FSW}.

The semiconductor substrate region 200S in the region R_{CMOS} has formed therein an N-type well region 200N (a well region) that includes an N-type impurity such as phosphorus (P), for example. The N-type well region 200N functions as a channel region of the P-channel MOS transistor Tr11 (FIG. 15).

The N-type well region 200N has formed therein semiconductor regions 301P (diffusion regions) that configure a source region and a drain region of the P-channel MOS transistor Tr11 (FIG. 15). These semiconductor regions 301P are connected to the via contact electrodes (contacts) CS functioning as the source electrode and the drain electrode of the P-channel MOS transistor Tr11.

Moreover, the P-channel MOS transistor Tr11 (FIG. 15) comprises: the insulating layer 200G (gate insulating layer) provided on a surface of the N-type well region 200N; and the electrode gc (gate electrode) provided on a surface of the insulating layer 200G. The electrode gc is connected to the via contact electrode (contact) CS functioning as the gate electrode of the P-channel MOS transistor Tr11.

A body contact region 302N in the region R_{CMOS} is provided in a part of the surface of the N-type well region 200N. A surface of the body contact region 302N is provided with the via contact electrode CS (contact) functioning as the substrate electrode of the P-channel MOS transistor Tr11 (FIG. 15). The body contact region 302N is an impurity region for contact, and includes an N-type impurity of the likes of phosphorus (P), that is, an impurity of the same conductive type as the N-type well region 200N. Impurity concentration of the body contact region 302N is higher than impurity concentration of the N-type well region 200N.

Moreover, the semiconductor substrate region 200S in the region R_{CMOS} has formed therein the semiconductor regions 301N (diffusion regions) that configure a source region and a drain region of the N-channel MOS transistor Tr12. These semiconductor regions 301N are connected to the via contact electrodes (contacts) CS functioning as the source electrode and the drain electrode of the N-channel MOS transistor Tr12.

Moreover, the N-channel MOS transistor Tr12 (FIG. 15) comprises: the insulating layer 200G (gate insulating layer) provided on the surface of the semiconductor substrate region 200S; and the electrode gc (gate electrode) provided on a surface of the insulating layer 200G. The electrode gc is connected to the via contact electrode (contact) CS functioning as the gate electrode of the N-channel MOS transistor Tr12.

In this way, the part of the plurality of transistors being the CMOS circuit, for example, include a transistor provided in the semiconductor substrate region 200S and a transistor provided in the N-type well region 200N in the region R_{CMOS}.

Note that FIG. 16 is a drawing for explaining a part of the configuration of the chip C_{P}, and does not show specific numbers, shape, arrangement, and so on of the configuration. Moreover, the CMOS circuit, which is one example of the part of the plurality of transistors, need only be a logic arithmetic element, and may be a plurality of CMOS circuits. The foot switch FSW being the object circuit according to the first embodiment need not be an N-channel MOS transistor, but may be a P-channel MOS transistor.

### Method of Manufacturing

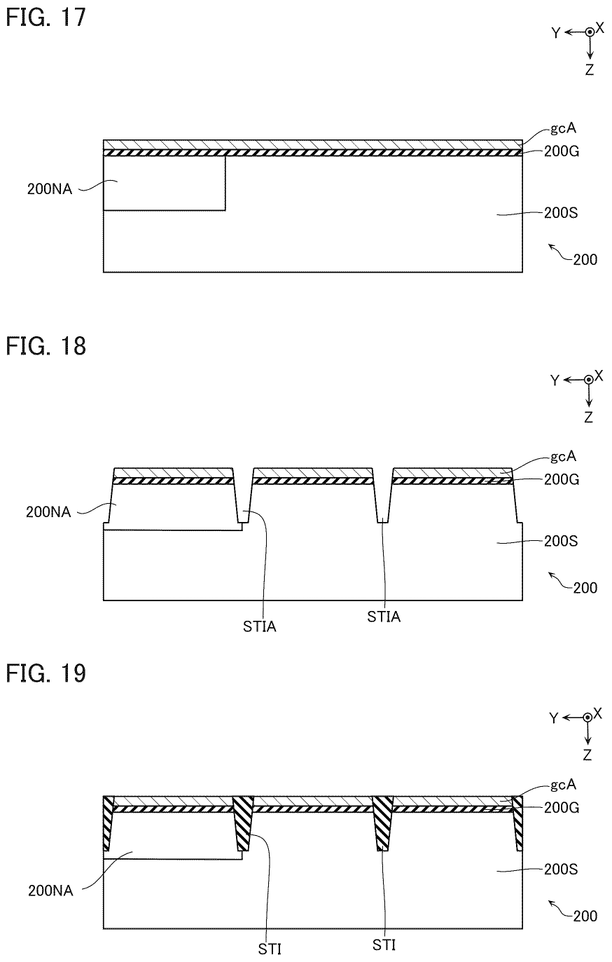

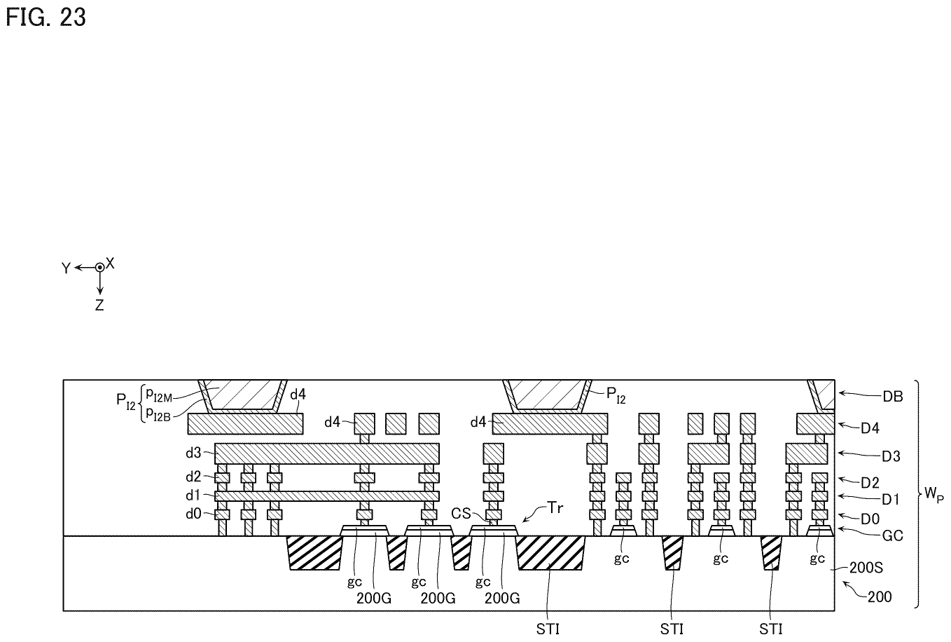

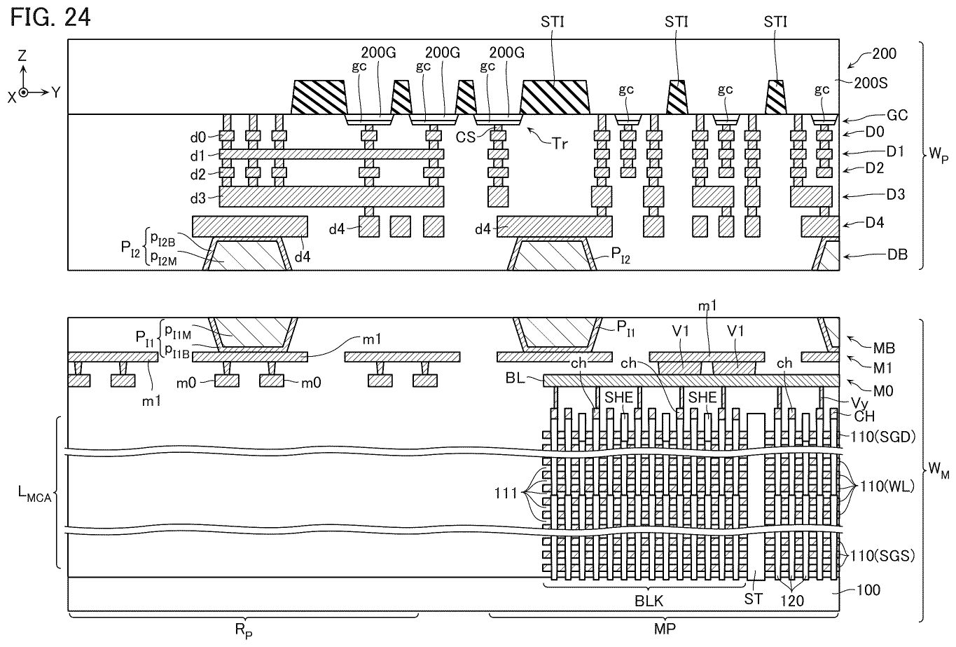

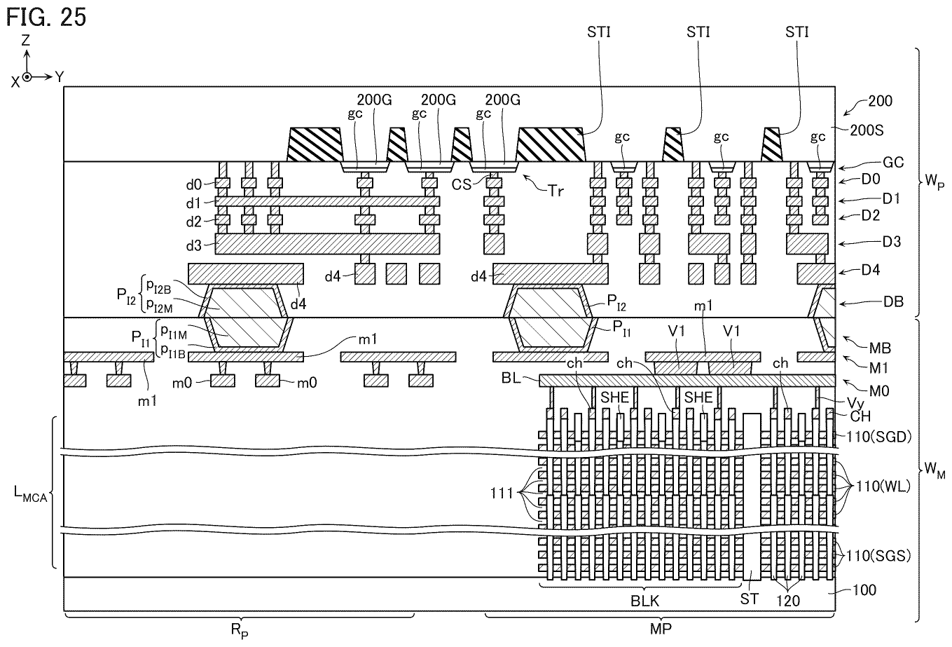

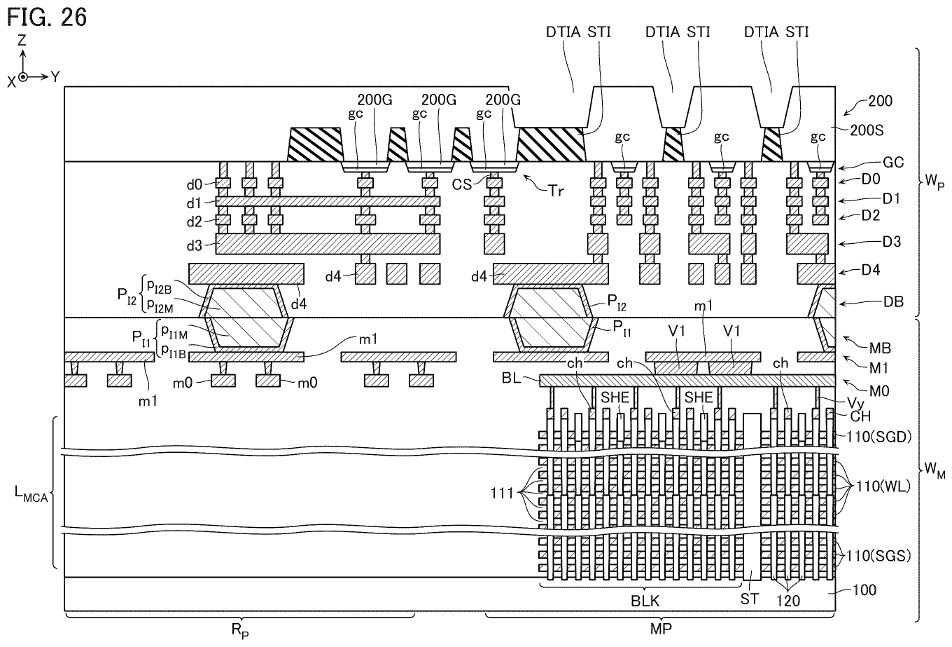

Next, a method of manufacturing the semiconductor memory device according to the first embodiment will be described with reference to FIGS. 17 to 32. FIGS. 17 to 23 are schematic cross-sectional views for explaining a method of manufacturing a CMOS portion of a wafer W_{P}. FIGS. 24 and 25 are schematic cross-sectional views for explaining a method of manufacturing by which a wafer W_{M} and the wafer W_{P} are bonded. FIGS. 26 to 32 are schematic cross-sectional views for explaining a method of manufacturing a semiconductor substrate 200 portion of the wafer W_{P}. Note that FIGS. 17 to 22 show cross sections corresponding to a part of FIG. 16. Moreover, FIGS. 23 to 32 show cross sections corresponding to FIG. 7.

### Method of Manufacturing CMOS Portion of Chip C_{P}

The method of manufacturing the CMOS portion of the chip C_{P}, that is, the wafer W_{P} will be described below. First, as shown in FIG. 17, an N-type well region 200NA is formed, and, in a surface of the semiconductor substrate 200, the insulating layer 200G is formed. In the step of forming the N-type well region 200NA, a mask having opened therein a region corresponding to the N-type well region 200NA is formed by photolithography, for example. Then, for example, by ion implantation treatment using said mask and a subsequent heat treatment, the N-type well region 200NA is formed close to the surface of the semiconductor substrate region 200S. The mask used in this step is removed after the ion implantation treatment. The step of forming the insulating layer 200G is performed by the likes of thermal oxidation, for example. Moreover, a conductive layer gcA including the likes of polysilicon is formed on a surface of the insulating layer 200G. This step is performed by the likes of CVD (Chemical Vapor Deposition), for example.

Next, as shown in FIG. 18, for example, an opening STIA is formed at a position corresponding to the insulating member STI described with reference to FIG. 7. The opening STIA extends in the Z-direction, and in the X-direction or the Y-direction, penetrates the conductive layer gcA and the insulating layer 200G, and divides a part of the front surface of the semiconductor substrate 200. This step is performed by a method such as RIE (Reactive Ion Etching), for example.

Next, an insulating layer is formed in the semiconductor substrate 200. This step is performed by the likes of CVD, for example. In this step, the opening STIA is filled in by the insulating layer. Then, a part of the formed insulating layer is removed to form a plurality of the insulating members STI, as shown in FIG. 19, for example. The step of removing a part of the formed insulating layer is performed by a method such as CMP (Chemical Mechanical Polishing), for example.

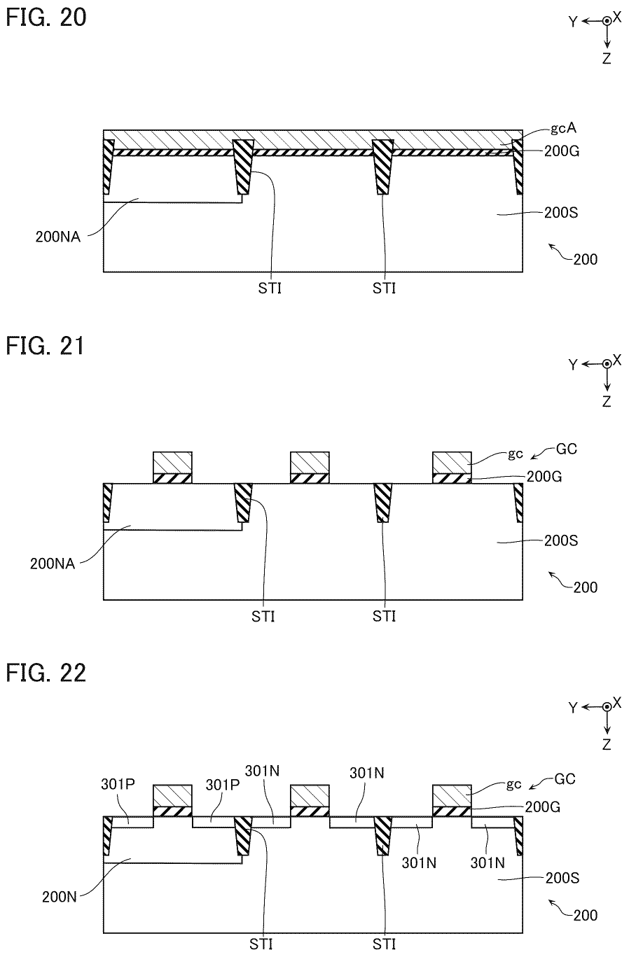

Next, as shown in FIG. 20, for example, a conductive layer gcA including the likes of tungsten (W) is formed on a surface of the conductive layer gcA. This step is performed by the likes of CVD, for example.

Next, as shown in FIG. 21, for example, parts of the conductive layer gcA and insulating layer 200G are removed to expose the surface of the semiconductor substrate 200 and thereby form a plurality of the electrodes gc. This step is performed by the likes of RIE, for example.

Next, as shown in FIG. 22, for example, the surface of the N-type well region 200N of the exposed semiconductor substrate 200 is implanted with a P-type impurity such as boron (B), for example, to form the semiconductor region 301P, and the surface of the exposed semiconductor substrate 200 is implanted with an N-type impurity such as phosphorus (P), for example, to form the semiconductor region 301N. This step is performed by the likes of ion implantation, for example.

Subsequently, the via contact electrodes CS and the wiring layers D2, D3, D4, DB described with reference to FIG. 7 are formed by a damascene process. In this way, as shown in FIG. 23, for example, the wafer W_{P} corresponding to the chip C_{P} is manufactured.

Steps from Bonding of Wafers W_{P}, W_{M} Onward

As shown in FIG. 24, the wafer W_{M} corresponding to the chip C_{M} is manufactured. Moreover, the wafer W_{P} and the wafer W_{M} are disposed so that a wafer W_{P} front surface side and a wafer W_{M} front surface side face each other.

Next, as shown in FIG. 25, the bonding electrode P_{I2} and bonding electrode P_{I1} are joined to bond the two wafers W_{M}, W_{P}. This bonding step is performed by a direct joining method on the bonding electrodes, for example.

### Method of Manufacturing Semiconductor Substrate 200 Portion of Chip C_{P}

Next, as shown in FIG. 26, for example, an opening DTIA is formed at a position corresponding to the insulating member DTI described with reference to FIG. 7. The opening DTIA extends in the Z-direction, and in the X-direction or the Y-direction, penetrates the semiconductor substrate 200, and exposes the upper end of the insulating member STI. Note that this step is performed by a method such as RIE, for example.

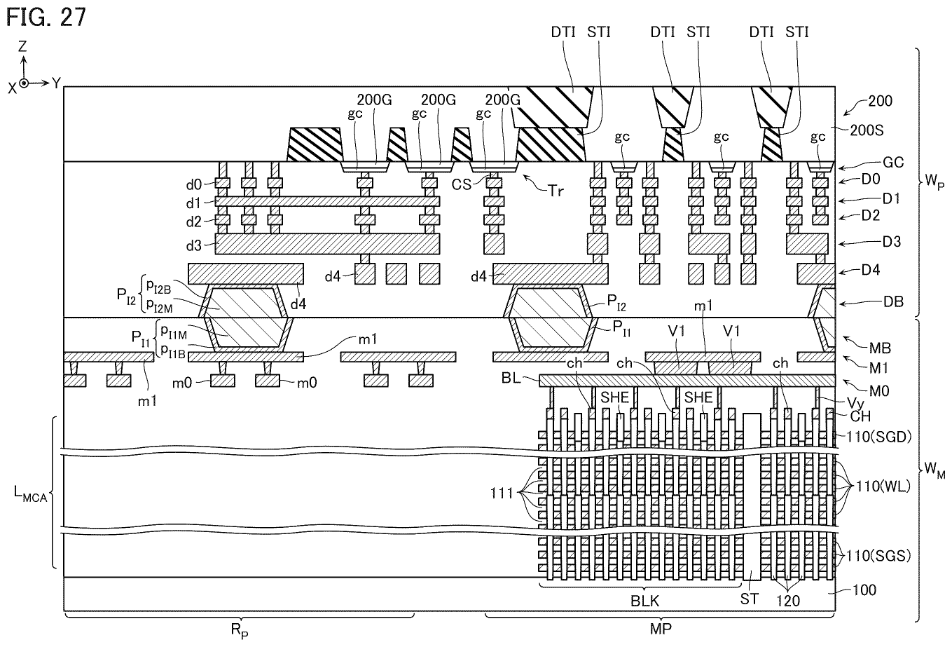

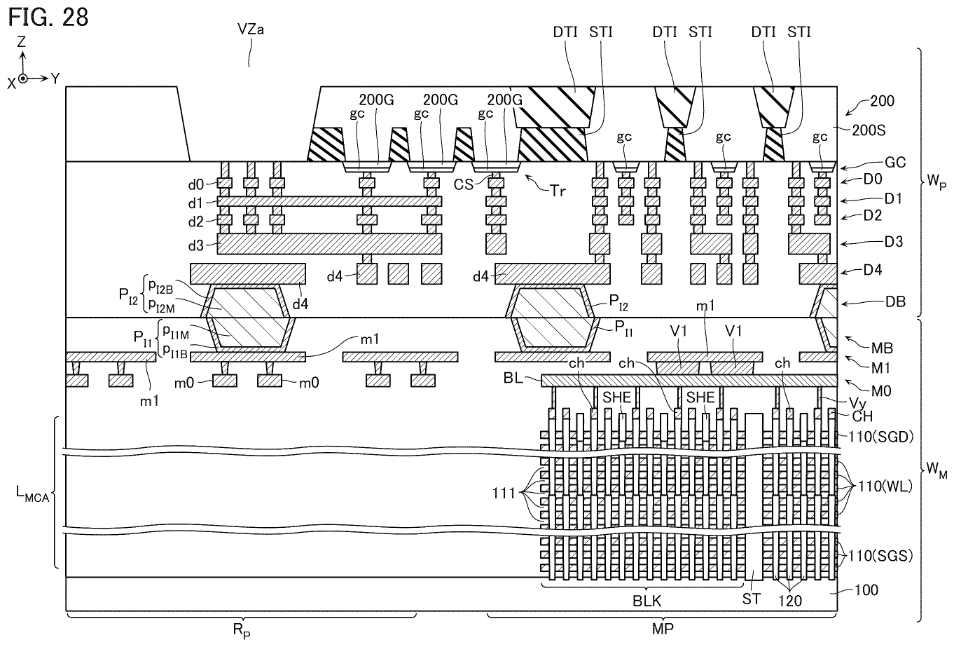

Next, an insulating layer is formed in the semiconductor substrate 200. This step is performed by the likes of CVD, for example. In this step, the opening DTIA is filled in by the insulating layer. Then, a part of the formed insulating layer is removed to form a plurality of the insulating members DTI, as shown in FIG. 27, for example. The step of removing a part of the formed insulating layer is performed by a method such as CMP, for example. Next, as shown in FIG. 28, for example, an opening VZa is formed at a position corresponding to the opening VZ described with reference to FIG. 7 of the semiconductor substrate 200. This opening VZa extends in the Z-direction, and in the X-direction or the Y-direction, penetrates the semiconductor substrate 200, and exposes the upper ends of a plurality of the via contact electrodes CS. This step is performed by a method such as RIE, for example.

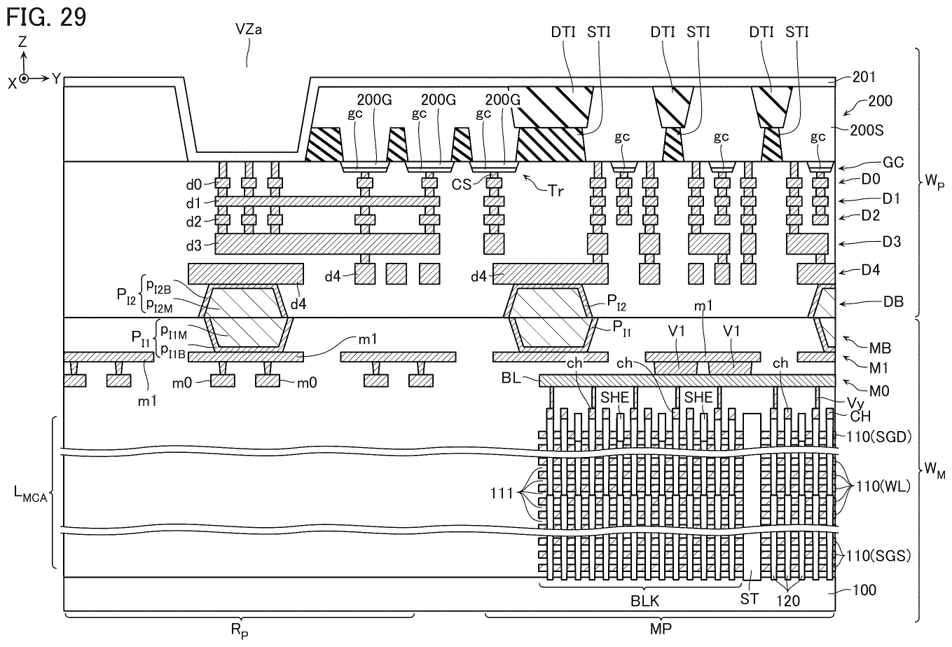

Next, as shown in FIG. 29, for example, the insulating layer 201 of the likes of silicon oxide is formed on a bottom surface and inner peripheral surface of the opening VZa, and on the upper surface of the semiconductor substrate 200. This step is performed by the likes of CVD, for example.

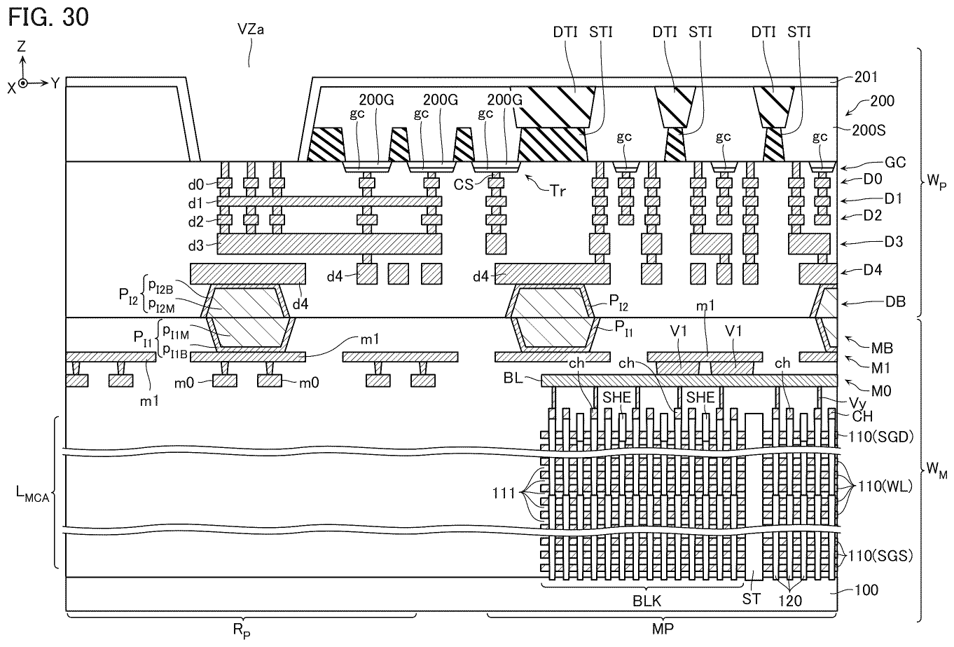

Next, as shown in FIG. 30, for example, the insulating layer 201 of the bottom surface of the opening VZa is removed, and the upper ends of the plurality of via contact electrodes CS are exposed. This step is performed by a method such as etching back by RIE, for example.

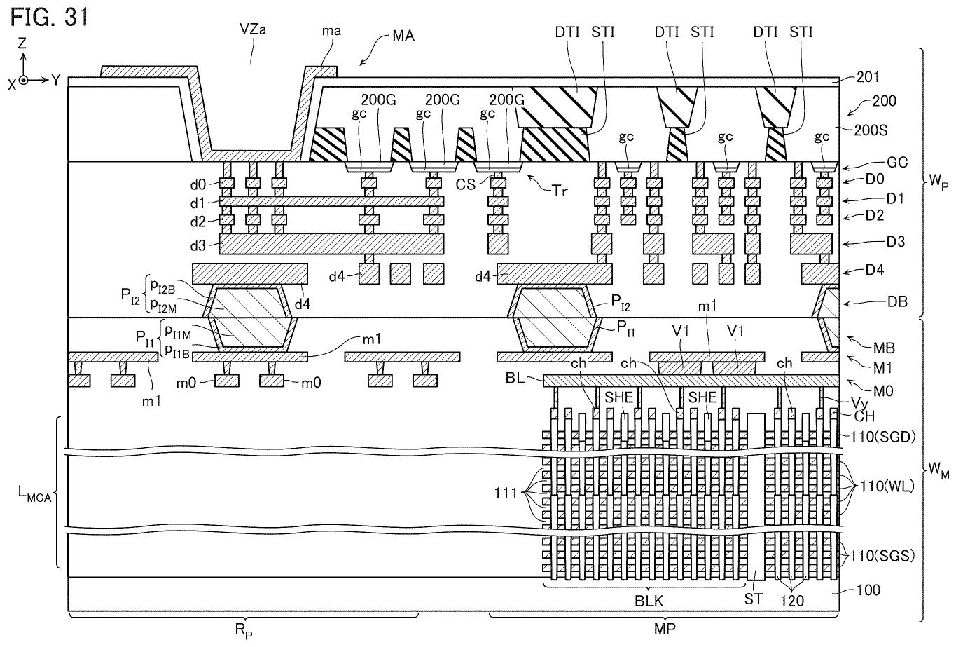

Next, as shown in FIG. 31, for example, a back surface wiring MA is formed on the bottom surface and inner peripheral surface of the opening VZa, and in a peripheral portion of the opening VZa. This step is performed by formation by the likes of CVD film formation and etching, for example.

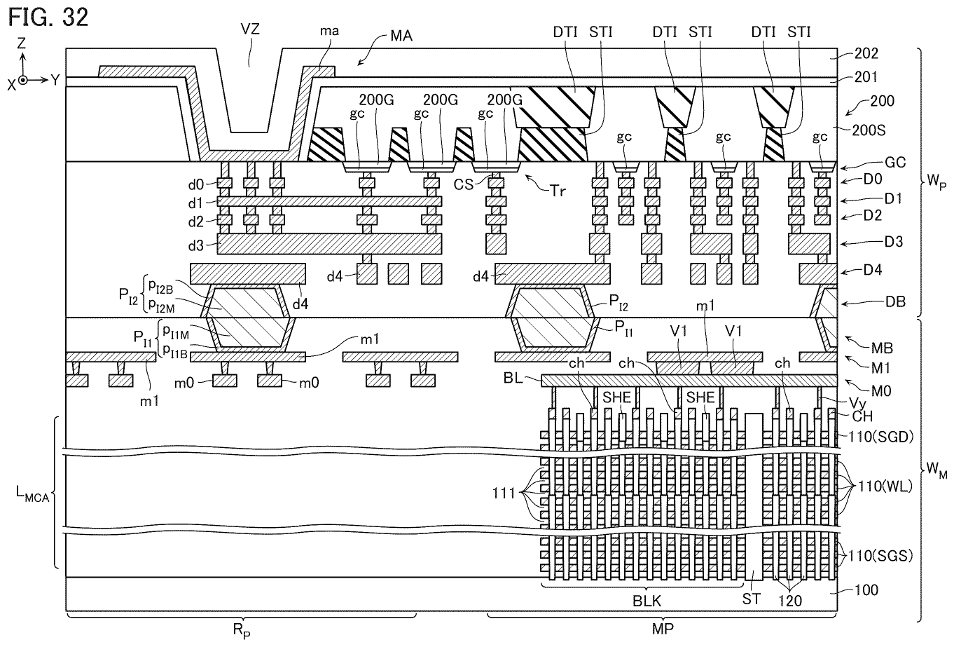

Next, as shown in FIG. 32, for example, the insulating layer 202 is formed on an upper surface of the structure shown in FIG. 31, and an opening is formed in the opening VZa of the insulating layer 202. This step is performed by methods such as CVD and RIE, for example.

Manufacturing of the semiconductor substrate 200 portion of the chip C_{P} is performed utilizing such back surface processing.

### Comparative Example

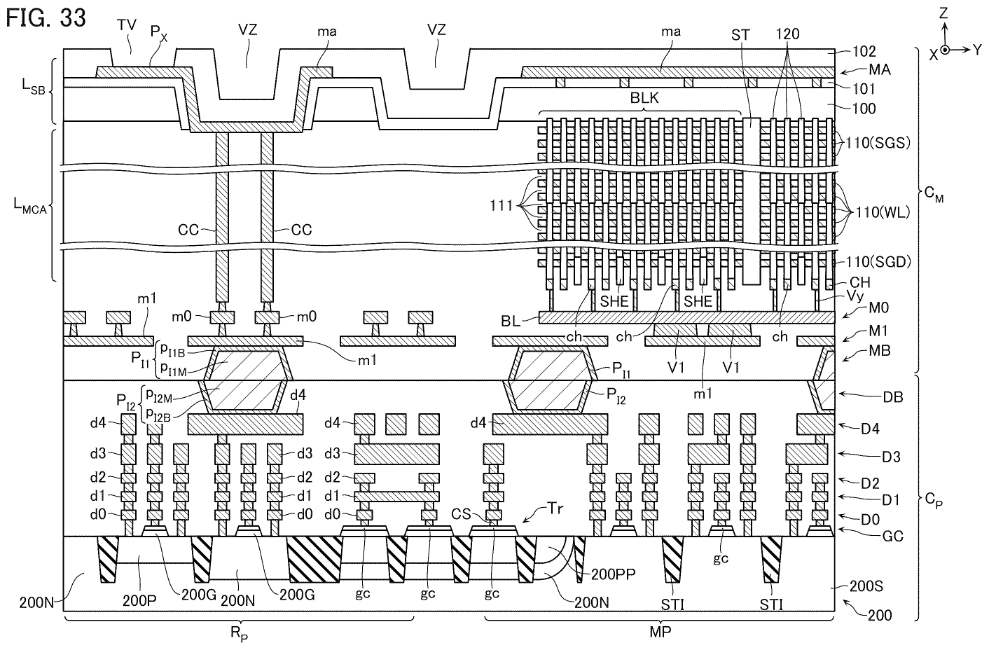

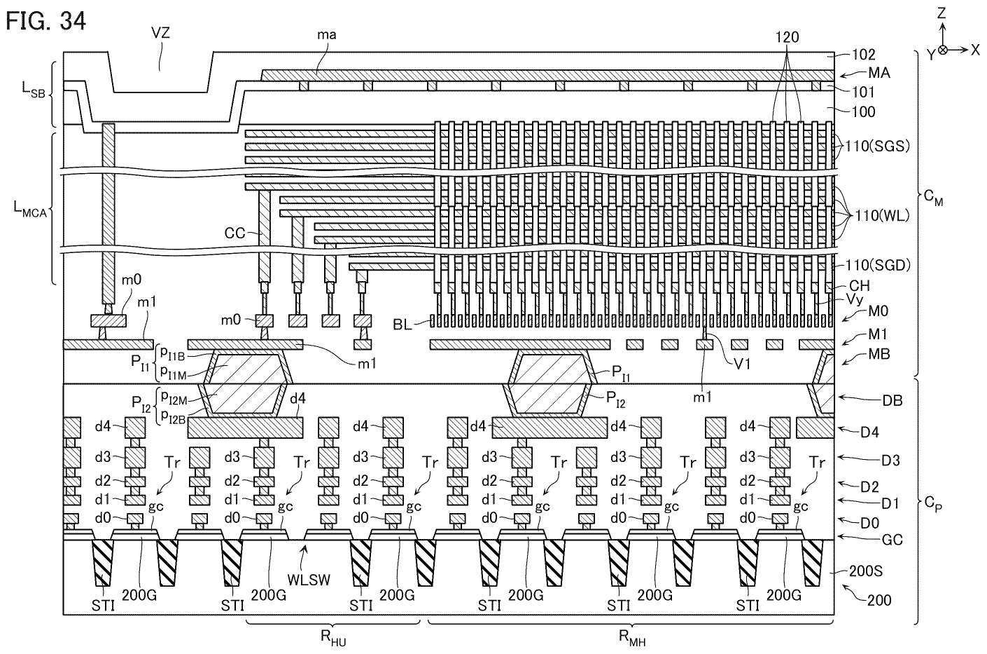

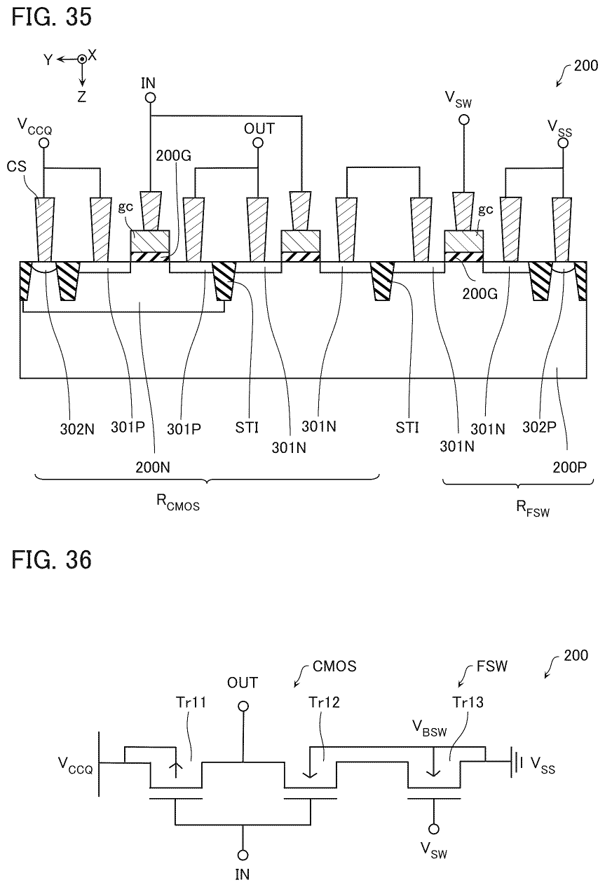

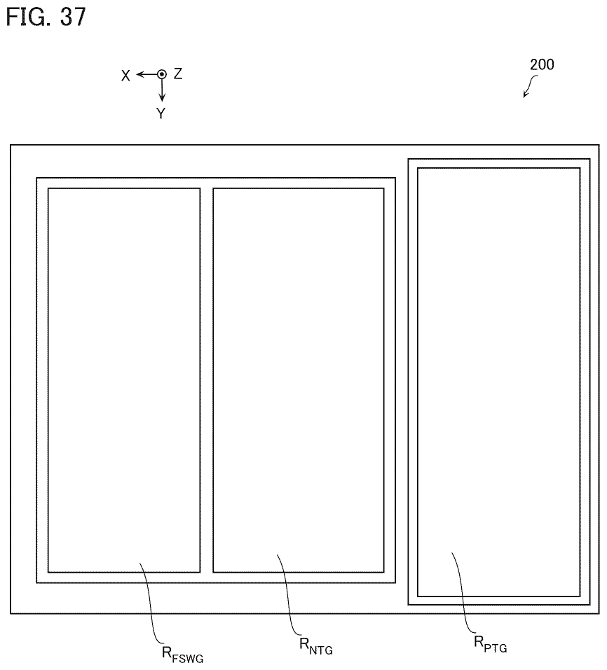

Next, a semiconductor memory device according to a comparative example will be described with reference to FIGS. 33 to 37. FIGS. 33 and 34 are schematic cross-sectional views showing a part of a configuration of a memory die MD according to the comparative example. FIG. 35 is a schematic cross-sectional view showing a connection relationship of a part of a plurality of transistors in a semiconductor substrate 200 and a configuration of an object circuit connected to these transistors, according to the comparative example. FIG. 35 exemplifies the part of the plurality of transistors in the semiconductor substrate 200 and the configuration of the object circuit connected to these transistors, in a circuit region R_{C} according to the comparative example. FIG. 36 is a circuit diagram exemplifying a circuit of the part of the plurality of transistors in the semiconductor substrate 200 and the object circuit connected to this circuit, according to the comparative example. In FIG. 36, a voltage V_{CQ} is a power supply voltage, and a voltage V_{SS} is a ground voltage. FIG. 37 is a plan view schematically showing circuit block areas occupied by configurations of the circuit of the part of the plurality of transistors in the semiconductor substrate 200 and the object circuit connected to this circuit, according to the comparative example. FIG. 37 shows: a region R_{PTG} occupied by a plurality of P-channel MOS transistors Tr11, of a CMOS circuit being the circuit of the part of the plurality of transistors; a region R_{NIG} occupied by a plurality of N-channel MOS transistors Tr12, of the CMOS circuit being the circuit of the part of the plurality of transistors; and a region R_{FSWG} occupied by a plurality of foot switches FSW being a plurality of the object circuits.

In the comparative example, as shown in FIGS. 32 and 33, the substrate layer L_{SB} is provided in the chip C_{M}, not the chip C_{P}.

Moreover, as shown in FIGS. 33 to 35, the semiconductor substrate 200 according to the comparative example is not provided with an insulating member DTI.

As shown in FIG. 35, the circuit region R_{C} according to the comparative example comprises: a region R_{FSW} which is a region of the semiconductor substrate 200 (a semiconductor substrate region 200S) surrounded by insulating members STI, and has the foot switch FSW formed therein; and a region R_{CMOS} which is a region of the semiconductor substrate 200 (the semiconductor substrate region 200S) surrounded by the insulating members STI, and has the CMOS circuit formed therein. Note that as mentioned above, the semiconductor substrate 200 according to the comparative example is not provided with the insulating member DTI. Therefore, a body of the N-channel MOS transistor Tr12 and body of an N-channel MOS transistor Tr13 are continuous, and a substrate voltage is common. As shown in FIG. 36, substrate electrodes of the N-channel MOS transistors Tr12, Tr13 are applied with the voltage V_{SS}.

In order for the CMOS circuit of the kind shown in FIG. 36 to be operated at high speed, it is preferable for thresholds of a P-channel MOS transistor Tr11 and the N-channel MOS transistor Tr12 configuring this CMOS circuit to be lowered, and for ON current I_{ON} to thereby be raised. However, in this case, a through-current (a leak current) when the CMOS circuit is not operating increases, and power consumption of the CMOS circuit increases.

Accordingly, in the comparative example, the foot switch FSW is inserted (added) between the CMOS circuit being a logic arithmetic element and the ground voltage V_{SS}. Setting the foot switch FSW to an OFF state when the CMOS circuit is not operating, for example, makes it possible for through-current (leak current) of the voltage V_{CCQ} for input/output circuit use and the ground voltage V_{SS}, to be suppressed. Note that the foot switch FSW is set to an ON state when the CMOS circuit is operating.

However, although the foot switch FSW suppresses the through-current (leak current) and thereby contributes to a lowering of power consumption, resistance R_{ON} of the foot switch FSW results in the foot switch FSW suppressing high-speed operation of the CMOS circuit when the CMOS circuit is operating.

Now, characteristics required of the foot switch FSW are: that OFF current I_{OFF} be small (that cut-off characteristics of the transistor configuring the foot switch FSW be good) in order to suppress through-current (leak current) when the CMOS circuit is not operating; and that resistance R_{ON} be small (that it be easy for current to flow when the transistor configuring the foot switch FSW is in an ON state) in order not to suppress operation of the CMOS circuit when the CMOS circuit is operating.

In the comparative example, in order to satisfy OFF current I_{OFF} being small of the required characteristics, threshold V_{TH} of the transistor configuring the foot switch FSW is set high, and in order to satisfy resistance R_{ON} being small of the required characteristics, a gate width W_{g} of the transistor configuring the foot switch FSW is set large. However, when the gate width W_{g} of the transistor configuring the foot switch FSW is set large, then circuit area of the foot switch FSW will become large, and chip area will increase. In the comparative example, as shown in FIG. 37, for example, area of the region R_{FSWG} where the foot switch FSW (transistor Tr13) is provided has ended up becoming as large as area of the region R_{NTG} where the N-channel MOS transistor Tr12 is provided. Circuit area thus increases by the foot switch FSW being added to the CMOS circuit.

Now, in order to reduce resistance R_{ON} of the foot switch FSW (transistor Tr13) and make OFF current I_{OFF} small without increasing circuit area, it is conceivable that, for example, when the CMOS circuit is not operating, substrate voltage of the transistor Tr13 configuring the foot switch FSW be controlled so that threshold V_{TH} of the transistor Tr13 will be set high, and its OFF current I_{OFF} will thus be made small. Moreover, it is conceivable that, for example, when the CMOS circuit is operating, substrate voltage of the transistor Tr13 configuring the foot switch FSW be controlled so that threshold V_{TH} of the transistor Tr13 will be set low, and its resistance R_{ON} will thus be made small.

However, as described with reference to FIGS. 33 to 35, the semiconductor substrate 200 according to the comparative example does not comprise the insulating member DTI, and the semiconductor substrate region 200S is not divided into a plurality of portions, either. Hence, sometimes, when, for example, a voltage larger than voltage V_{SS} is applied to a P-type well region 200P, latch-up occurs, and so on.

### Advantages of Semiconductor Memory Device According to First Embodiment

In the semiconductor memory device according to the first embodiment, as shown in FIG. 16, for example, a part of the insulating members STI has the insulating member DTI formed at a position overlapping them viewed from the Z-direction. Such a configuration makes it possible for fellow substrate regions of region R_{CMOS} having the CMOS circuit formed therein and region R_{FSW} adjacent in the Y-direction to region R_{CMOS} and having the foot switch FSW formed therein, to be electrically isolated via the insulating member DTI and the insulating member STI. This results in that, as shown in FIG. 16, by forming the body contact region 302P in region R_{FSW} and controlling a voltage V_{BSW} applied thereto, substrate voltage of the foot switch FSW can be controlled independently of substrate voltage of the CMOS circuit. In other words, threshold V_{TH} of the transistor configuring the foot switch FSW can be controlled independently of threshold of the CMOS circuit. Moreover, since resistance R_{ON} of the transistor configuring the foot switch FSW can be made small by controlling its threshold V_{TH}, it ceases to be necessary for a gate width W_{g} of the foot switch FSW to be made large even in the case of the foot switch FSW having been added to the CMOS circuit, and increase in circuit area can be suppressed.

Note that in the chip C_{P} according to the comparative example shown in FIG. 33, for example, the semiconductor substrate region 200S (P-type well region 200P) is provided with an N-type well region 200N (well) and a P-type well region 200PP. The P-type well region 200PP is provided at a position overlapping the N-type well region 200N viewed from the Z-direction, and includes a P-type impurity such as boron (B). There is a possibility that employing a structure of the kind where the semiconductor substrate region 200S (P-type well region 200P) is provided with an N-type well region 200N and a P-type well region 200PP in this way will enable the foot switch FSW and the CMOS circuit to be electrically isolated. However, when such a structure is employed to electrically isolate the foot switch FSW and the CMOS circuit, there is a risk that circuit area of the foot switch FSW cannot be suppressed. Moreover, when such a structure is employed, there will be a thyristor-structured portion, and not only will adjustment of timing at which a forward bias voltage V_{BSW} is to be applied to the body contact region 302P be difficult, but there will be a latch-up risk too. In this respect, in the present embodiment, since the semiconductor substrate region 200S is physically divided into the region R_{FSW} and region R_{CMOS} by the insulating members STI, DTI, there is no need for such a structure to be employed, and there is no thyristor-structured portion. Therefore, since latch-up will not occur even when joining is in an ON state for some time, the latch-up risk is low, and adjustment of the timing at which a forward bias voltage V_{BSW} is to be applied to the body contact region 302P becomes easy.

Moreover, it is conceivable too that, for example, in the chip C_{P} according to the comparative example, fellow substrate regions of region R_{CMOS} where the CMOS circuit is formed and region R_{FSW} where the foot switch FSW is formed, be isolated solely by the insulating member STI. However, it is difficult for the opening STIA (refer to FIG. 18) corresponding to the insulating member STI to have its length in the Z-direction lengthened without a width in the X-direction (or Y-direction) of the insulating member STI being changed, due to the opening STIA having a tapered shape.

In contrast, in the present embodiment, the insulating member STI and the insulating member DTI can be formed by separate processes, and the insulating member DTI can be formed by back surface processing. Due to this kind of configuration, the insulating member STI can be formed more easily compared to the case of it being formed long in the Z-direction. Moreover, since a width in the X-direction (or Y-direction) of the insulating member DTI can be formed larger than the width in the X-direction (or Y-direction) of the insulating member STI, the insulating member DTI can easily be formed to the position of the insulating member STI from the back surface of the semiconductor substrate 200. That is, processing dimensions for processing an insulating region electrically isolating between adjacent word line switches WLSW can be eased, so manufacturing costs can be suppressed.

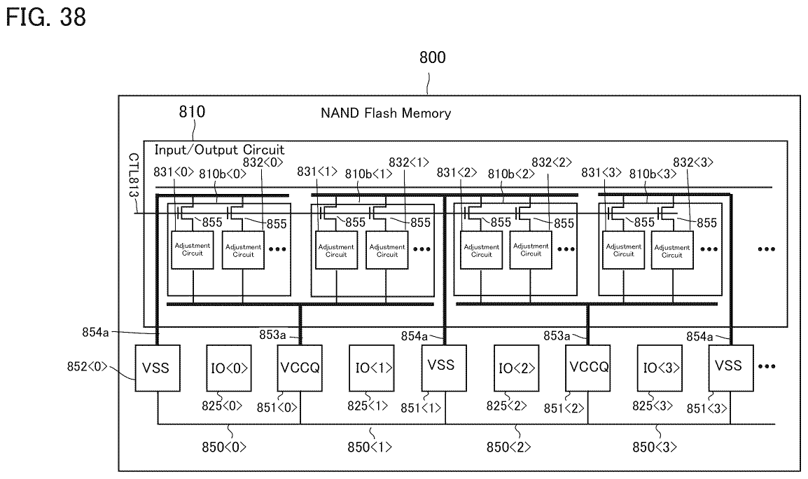

Note that although, as shown in FIGS. 15 and 16, there has been described an example where the foot switch FSW according to the first embodiment is added to the CMOS circuit (logic arithmetic element) to be used in the input/output circuit, the present invention is not limited to this. The foot switch FSW according to the first embodiment may be used added to a data bus or logic arithmetic element other than a data bus. Moreover, as shown in FIG. 38, the foot switch FSW according to the first embodiment may be employed in an input/output circuit 810 different from the above-mentioned input/output circuit. Although there has been described an example where the CMOS circuit according to the first embodiment is configured by a P-channel MOS transistor acting as a pull-up side transistor and an N-channel MOS transistor acting as a pull-down side transistor, the present invention is not limited to this. For example, the CMOS circuit may be configured by an N-channel MOS transistor acting as the pull-up side transistor and a P-channel MOS transistor acting as the pull-down side transistor.

### Configuration of Input/Output Circuit 810

FIG. 38 is a schematic block diagram showing the separate input/output circuit 810 where the foot switch FSW according to the first embodiment is used. Note that in FIG. 38, a part of configuration are omitted. IO pads 825 <0> to 825 <3>, VCCQ pads 851 <0> to 851 <3>, and a VSS pad 852 <0> shown in FIG. 38 correspond to the external pad electrode P_{X} shown in FIG. 5, and so on, for example.

The input/output circuit 810 is included in a NAND type flash memory 800, for example. The NAND type flash memory 800 is basically configured similarly to the memory die MD (FIG. 1). However, the NAND type flash memory 800 comprises the input/output circuit 810, instead of the input/output control circuit I/O.

As shown in FIG. 38, an IO circuit area 850 <0> includes an output circuit 810b <0>, the IO pad 825 <0>, the VCCQ pad 851 <0>, the VSS pad 852 <0>, a wiring 853a, a wiring 854a, and a plurality of transistors 855 being N-channel MOS transistors.

Gates of the plurality of transistors 855 are each inputted with a control signal CTL813 from a logic control circuit. One ends of the plurality of transistors 855 are each connected to the wiring 854a. Other ends of the plurality of transistors 855 are respectively connected to a plurality of wirings. At least one of the plurality of transistors 855 is provided to each circuit unit where an operation is completed within one cycle (a shortest cycle) of a clock signal CLK. For example, one of the plurality of transistors 855 can be provided to each of adjustment circuits 831 <0>, 832 <0>. In IO circuit areas 850 <1> to 850 <3> too, a plurality of the transistors 855 are provided similarly to in the IO circuit area 850 <0>.

In the IO circuit area 850 <0>, the wiring 853a is connected to the VCCQ pad 851 <0>. Each circuit unit (adjustment circuit 831 <0>, adjustment circuit 832 <0>, . . . ) in the output circuit 810b <0> is connected to the wiring 853a connected to the VCCQ pad 851 <0>, via a wiring.

Moreover, in the IO circuit area 850 <0>, the wiring 854a is connected to the VSS pad 852 <0>. Each circuit unit in the output circuit 810b <0> is connected to the wiring 854a connected to the VSS pad 852 <0>, via a wiring and the transistor 855.

Each circuit unit (adjustment circuit 831 <0>, adjustment circuit 832 <0>, . . . ) in the output circuit 810b <0> includes the CMOS circuit and foot switch FSW according to the first embodiment. The IO circuit areas 850 <1> to 850 <3> are similar to the above-mentioned IO circuit area 850 <0>, hence descriptions thereof will be omitted.

### Second Embodiment

The object circuit according to the first embodiment has been described assuming it to be the foot switch FSW formed in a region of the semiconductor substrate 200 (semiconductor substrate region 200S) surrounded by the insulating members DTI and the insulating members STI, and assuming threshold of the transistor Tr13 configuring the foot switch FSW to be adjusted by the control circuit for adjusting electrical characteristics of this object circuit. However, the present invention is not limited to this.

An object circuit according to a second embodiment will be described assuming it to be a resistance element formed in a region of the semiconductor substrate 200 (semiconductor substrate region 200S) surrounded by the insulating members DTI and the insulating members STI, and assuming a resistance value of the resistance element to be adjusted by the control circuit for adjusting electrical characteristics of this object circuit. Note that the object circuit according to the second embodiment is used in the voltage generating circuit VG described with reference to FIG. 1.

### Configuration

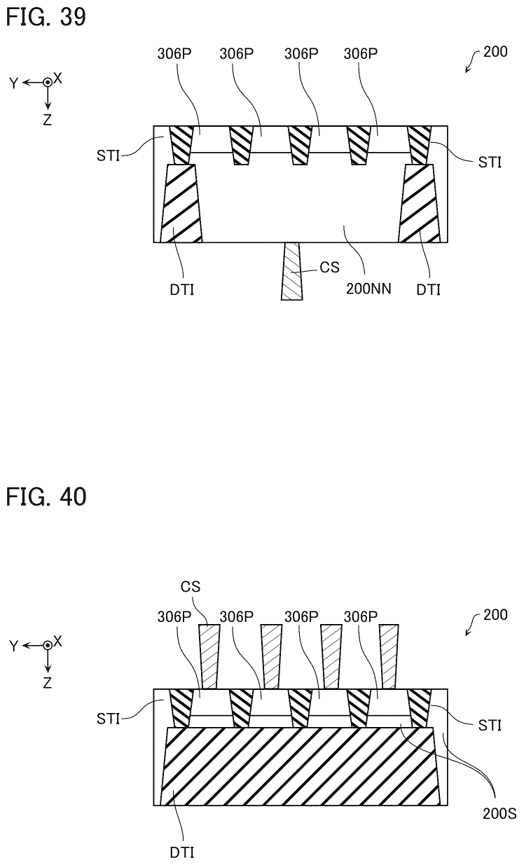

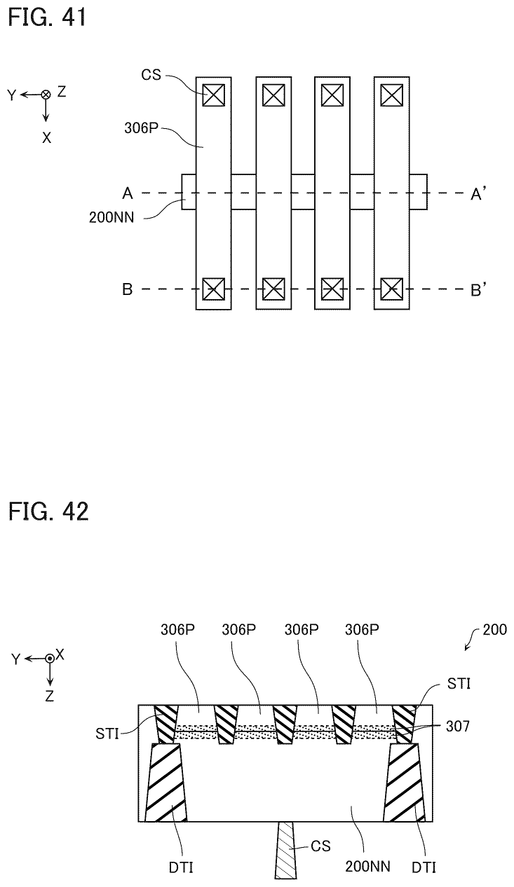

FIGS. 39 and 40 are schematic cross-sectional views showing a part of a configuration of a semiconductor memory device according to the second embodiment. FIGS. 39 and 40 exemplify a configuration of the resistance element being the object circuit provided in the semiconductor substrate 200, in the voltage generating circuit VG (FIG. 12). FIG. 39 shows a cross section taken along the dotted line A-A′ of FIG. 41, and FIG. 40 shows a cross section taken along the dotted line B-B′ of FIG. 41. FIG. 41 is a schematic bottom view showing the configuration of the resistance element shown in FIG. 39. FIG. 42 is an explanatory diagram for explaining a variable resistance mechanism of the resistance element shown in FIG. 39. Note that FIGS. 39, 41, and 42 are drawings for explaining a part of the configuration of the chip C_{P}, and do not show specific numbers, shape, arrangement, and so on of the configuration.

As shown in FIG. 39, a front surface of the region of the semiconductor substrate 200 (semiconductor substrate region 200S) surrounded by the insulating members DTI and the insulating members STI has formed therein a plurality of P+ layers 306P configuring a diffusion resistance. An N+ layer 200NN is formed on a back surface of a part of the P+ layer 306P. In the example of FIG. 41, the plurality of P+ layers 306P are arranged in the Y-direction, and each extend in the X-direction. Moreover, the N+ layer 200NN extends in the X-direction so as to intersect the plurality of P+ layers 306P viewed from the Z-direction.

Moreover, one end portions and the other end portions in the X-direction of the plurality of P+ layers 306P are each connected to the via contact electrode CS. As shown in FIG. 40, these plurality of via contact electrodes CS are connected from a front surface to the P+ layers 306P. Moreover, as shown in FIG. 39, the N+ layer 200NN is connected from its back surface with a via contact electrode CS.

The N+ layer 200NN includes an N-type impurity such as phosphorus (P), for example. The P+ layer 306P includes a P-type impurity such as boron (B), for example. Impurity concentration of the P+ layer 306P is higher than impurity concentration of the semiconductor substrate 200 (semiconductor substrate region 200S).

The plurality of P+ layers 306P each function as a resistance element connected between a pair of the via contact electrodes CS arranged in the X-direction (FIG. 41). In the present embodiment, a resistance value of the P+ layer 306P can be changed according to a voltage applied to the N+ layer 200NN.

Now, as shown in FIG. 42, when the N+ layer 200NN is applied with a voltage representing a reverse bias of a PN junction, a depletion layer 307 will extend. The depletion layer 307 does not allow carriers to flow therein, so when the depletion layer 307 extends, a wiring width in a current path between the via contact electrodes CS will decrease, and the resistance value of the P+ layer 306P will increase.

Therefore, in the present embodiment, the P+ layer 306P functions as a variable resistance having a variable resistance value corresponding to an input voltage to the N+ layer 200NN. Specifically, by a voltage applied to the via contact electrode CS connected to the back surface of the N+ layer 200NN being controlled by the control circuit, the P+ layer 306P is controlled as a variable resistance. Note that by the voltage applied to the via contact electrode CS connected to the back surface of the N+ layer 200NN being controlled to two values by the control circuit, the resistance value of the P+ layer 306P may be controlled as a variable resistance taking two values.

### Method of Manufacturing

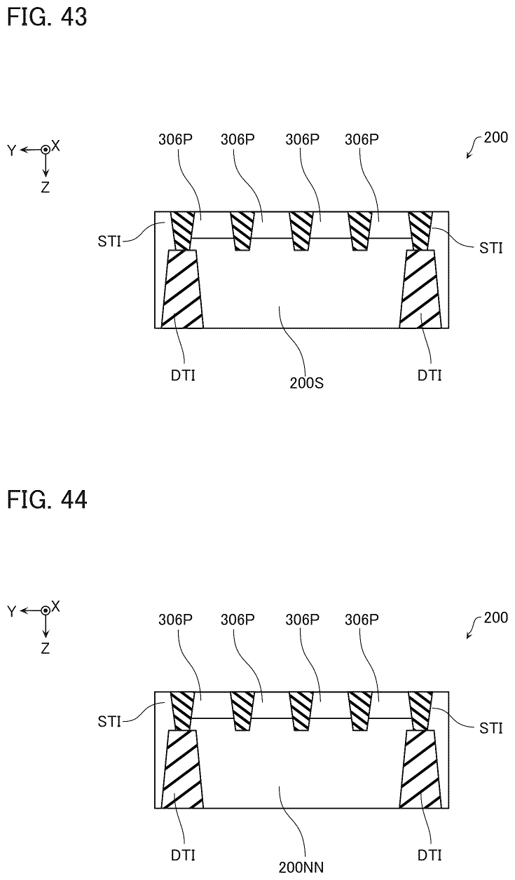

Next, a method of manufacturing the semiconductor memory device according to the second embodiment will be described with reference to FIGS. 43 and 44. FIGS. 43 and 44 are schematic cross-sectional views for explaining a method of manufacturing a portion of the object circuit according to the second embodiment. Note that FIGS. 43 and 44 show cross sections corresponding to FIG. 39. First, as shown in FIG. 43, the P+ layer 306P and a plurality of the insulating members STI are formed, and then a plurality of the insulating members DTI are formed at positions corresponding to a part of the plurality of insulating members STI. The step of forming the P+ layer 306P is performed by the likes of ion implantation, for example. Note that the step of forming the plurality of insulating members STI and step of forming the plurality of insulating members DTI are similar to in the first embodiment, hence descriptions thereof will be omitted.

Next, as shown in FIG. 44, for example, the N+ layer 200NN is formed on the back surface of the part of the P+ layer 306P. In the step of forming the N+ layer 200NN, the N+ layer 200NN is formed by the semiconductor substrate region 200S being implanted with an N-type impurity such as phosphorus (P) by the likes of PD (Plasma Doping), for example, from the exposed back surface of the semiconductor substrate 200, for example.

Subsequently, the via contact electrode CS on the back surface is formed to enable a structure of the kind shown in FIGS. 39 and 40, for example.

Manufacturing of the portion of the object circuit according to the second embodiment is performed utilizing such back surface processing.

### Comparative Example

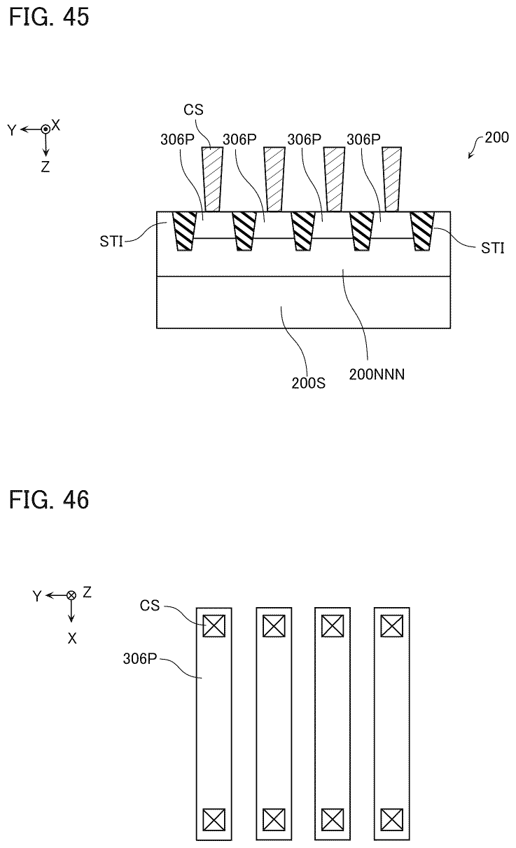

Next, a semiconductor memory device according to a comparative example will be described with reference to FIGS. 45 and 46. FIG. 45 is a schematic cross-sectional view showing a part of the configuration of the semiconductor memory device according to the comparative example. FIG. 46 is a schematic bottom view showing configuration of a resistance element shown in FIG. 45.

The semiconductor substrate 200 according to the comparative example is not provided with the insulating member DTI.

Moreover, the semiconductor substrate 200 according to the comparative example is provided with an N-type well region 200NNN, and a plurality of the P+ layers 306P are provided within the N-type well region 200NNN. The N-type well region 200NNN includes an N-type impurity such as phosphorus (P), for example.

The plurality of P+ layers 306P in the N-type well region 200NNN can be used as a resistor. That is, the plurality of P+ layers 306P according to the comparative example configure a diffusion resistance. As shown in FIG. 46, although spaces between via contact electrodes CS arranged in the X-direction of each of the plurality of P+ layers 306P according to the comparative example represent a resistance, they have a certain (fixed) resistance value.

In the plurality of P+ layers 306P according to the comparative example, joining (electrically connecting) two P+ layers 306P in parallel enables their resistance value to be halved. Similarly, in the plurality of P+ layers 306P according to the comparative example, joining (electrically connecting) two P+ layers 306P in series enables their resistance value to be doubled. Changing a manner of joining the P+ layers 306P in this way enables the numbers or lengths of P+ layers 306P to be changed, and hence allows a variety of resistance values to be created. However, when a plurality of the P+ layers 306P according to the comparative example are utilized to create a variety of resistance values, a large number of the P+ layers 306P need to be arranged, and circuit area increases.

### Advantages of Semiconductor Memory Device According to Second Embodiment

As described with reference to FIGS. 39 to 41, the semiconductor substrate 200 between adjacent insulating members DTI and the insulating members STI viewed from the Z-direction comprises the semiconductor substrate region 200S including a P-type impurity. The semiconductor substrate region 200S comprises: the P+ layer 306P which includes a P-type impurity and is provided in the front surface of the semiconductor substrate 200; and the N+ layer 200NN which includes an N-type impurity and is provided on a back surface side of the P+ layer 306P. The object circuit according to the second embodiment is the P+ layer 306P configuring a diffusion resistance.

Such a configuration results in that by a voltage applied to the via contact electrode CS (a back surface contact) electrically connected to the N+ layer 200NN being controlled by an unillustrated control circuit, the P+ layer 306P can have a resistance value that accords with the applied voltage.

In the semiconductor memory devices of recent years, a large number of voltage conditions have become required in memory cell operations (a read operation, a write operation, and an erase operation), and output voltages are adjusted by a ladder type resistance after several kinds of voltages (a program voltage VPGM, and so on) have been created by the voltage generating circuit VG (FIG. 1). For example, in the write operation of a memory cell MC, the program voltage VPGM is increased in fine voltage steps while threshold voltage of the memory cell MC is verified by a verify operation. These voltage steps will become finer as degree of multi-valuing of the memory cell MC rises. Moreover, in order to make the voltage steps fine, a ladder type resistance circuit used as a variable resistance will need to have a large number of resistance elements with fine resistance values disposed therein. This will result in area of the resistance elements increasing. In this respect, when a plurality of the P+ layers 306P according to the second embodiment are utilized to create a variety of resistance values, a plurality of resistance values can be expressed by a single P+ layer 306P, so there is no need for a large number of the P+ layers 306P to be arranged, and an increase in circuit area can be suppressed.

### Modified Example

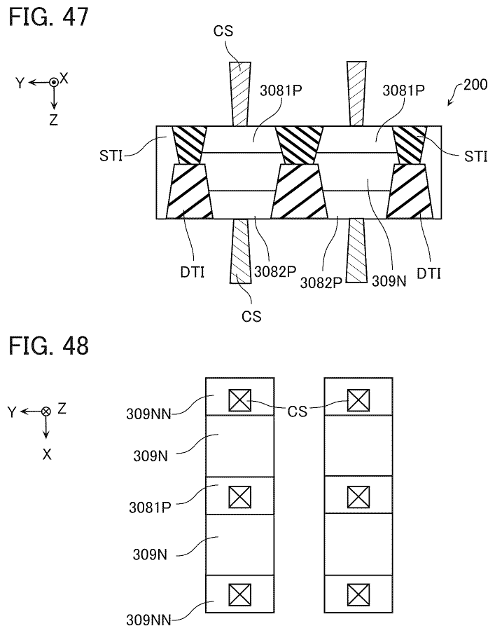

The object circuit according to the second embodiment has been described assuming it to be a diffusion resistance (the P+ layer 306P), as shown in FIG. 39. However, it may be a well resistance. This will be described below with reference to FIGS. 47 to 50.

### Configuration

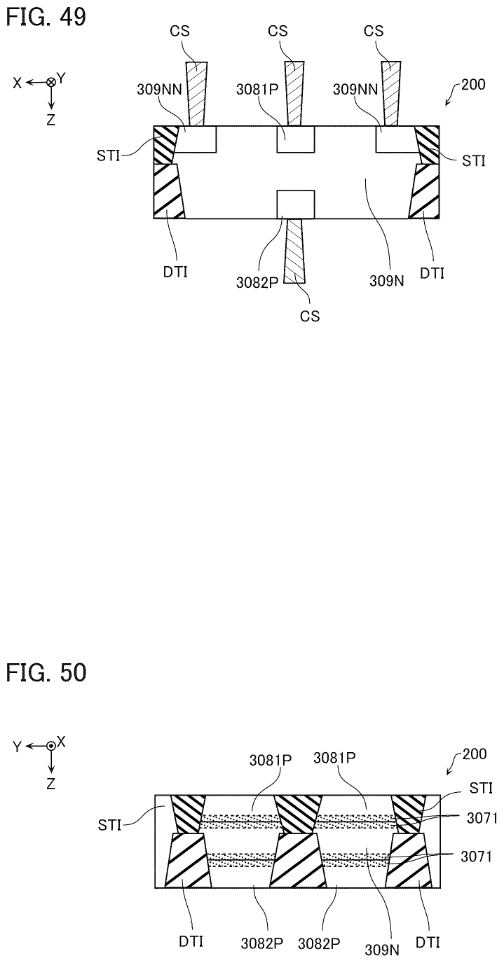

FIG. 47 is a schematic cross-sectional view showing a part of a configuration of a semiconductor memory device according to a modified example of the second embodiment. FIG. 47 exemplifies configuration of a resistance element being the object circuit provided in the semiconductor substrate 200, in the voltage generating circuit VG. FIG. 48 is a schematic bottom view showing configuration of the resistance element shown in FIG. 47. FIG. 49 is a schematic cross-sectional view showing configuration of the resistance element shown in FIG. 47. FIG. 50 is an explanatory diagram for explaining a variable resistance mechanism of the resistance element shown in FIG. 47. Note that FIGS. 47 to 50 are drawings for explaining a part of the configuration of the chip CP, and do not show specific numbers, shape, arrangement, and so on of the configuration. Moreover, FIGS. 47 to 50 correspond to FIGS. 39 to 42, and configurations of FIGS. 47 to 50 that are the same as in FIGS. 39 to 42 are assigned with the same symbols as in FIGS. 39 to 42, and duplicated descriptions thereof omitted.

As shown in FIG. 47, a region of the semiconductor substrate 200 surrounded by the insulating members DTI and the insulating members STI has formed therein an N-type well region 309N configuring a well resistance. In the example of FIGS. 47 to 49, a plurality of the N-type well regions 309N are arranged in the Y-direction, and each extend in the X-direction.

Moreover, one end portions and the other end portions in the X-direction of front surfaces of the plurality of N-type well regions 309N respectively have formed thereon N+ layers 309NN. The N+ layers 309NN are each connected with a via contact electrode CS. As shown in FIGS. 47 and 49, these plurality of via contact electrodes CS are connected to the N+ layers 309NN from a front surface of the N+ layers 309NN.

Moreover, at positions between pairs of N+ layers 309NN, on the front surfaces of the plurality of N-type well regions 309N, there are formed respective P+ layers 3081P. Moreover, at positions overlapping the P+ layers 3081P viewed from the Z-direction, on back surfaces of the plurality of N-type well regions 309N, there are formed P+ layers 3082P. The P+ layer 3081P is connected with a via contact electrode CS from the front surface, and the P+ layer 3082P is connected with a via contact electrode CS from the back surface (upper surface).

The N-type well region 309N includes an N-type impurity such as phosphorus (P), for example. The P+ layer 3081P and P+ layer 3082P include a P-type impurity such as boron (B), for example. Impurity concentrations of the P+ layer 3081P and P+ layer 3082P are higher than impurity concentration of the semiconductor substrate 200 (semiconductor substrate region 200S).

The plurality of N-type well regions 309N each function as a resistance element connected between a pair of the via contact electrodes CS arranged in the X-direction. In the present modified example, a resistance value of the N-type well region 309N can be changed according to voltages applied to the P+ layer 3081P and P+ layer 3082P.

Now, as shown in FIG. 50, when the P+ layer 3081P and P+ layer 3082P are applied with voltages representing a reverse bias of a PN junction, a depletion layer 3071 will extend. The depletion layer 3071 does not allow carriers to flow therein, so when the depletion layer 3071 extends, a wiring width in a current path between the via contact electrodes CS will decrease, and the resistance value of the N-type well region 309N will increase.

Therefore, in the present modified example, the N-type well region 309N functions as a variable resistance having a variable resistance value corresponding to input voltages to the P+ layer 3081P and P+ layer 3082P. Specifically, by voltages applied to the via contact electrodes CS connected to the P+ layer 3081P and P+ layer 3082P being controlled by the control circuit, the N-type well region 309N is controlled as a variable resistance. Note that by the voltages applied to the via contact electrodes CS connected to the P+ layer 3081P and P+ layer 3082P being controlled to two values by the control circuit, the resistance value of the N-type well region 309N may be controlled as a variable resistance taking two values.

### Method of Manufacturing

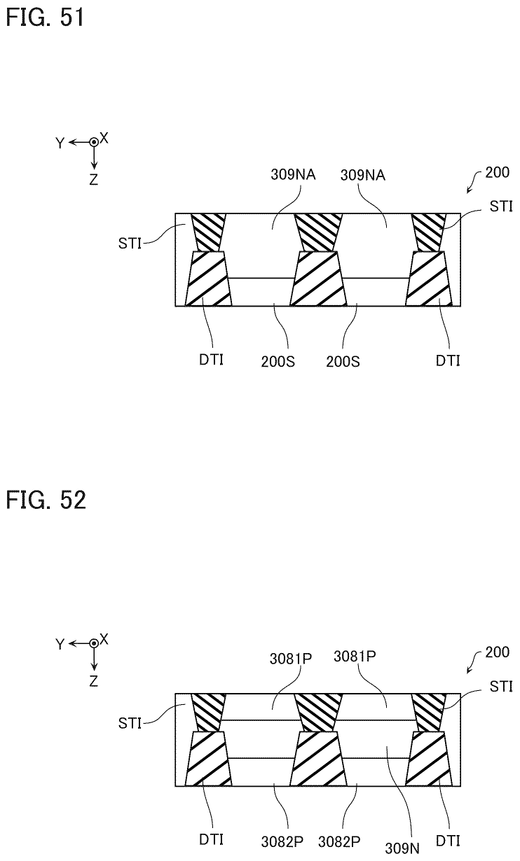

Next, a method of manufacturing the semiconductor memory device according to the modified example of the second embodiment will be described with reference to FIGS. 51 and 52. FIGS. 51 and 52 are schematic cross-sectional views for explaining a method of manufacturing a portion of the object circuit according to the modified example of the second embodiment. Note that FIGS. 51 and 52 show cross sections corresponding to FIG. 47.

First, as shown in FIG. 51, an N-type well region 309NA is formed, and then a plurality of the insulating members STI and insulating members DTI are formed. The step of forming the N-type well region 309NA is performed by implementing ion implantation processing on the semiconductor substrate region 200S, for example. Note that the step of forming the insulating member STI and the step of forming the insulating member DTI have been described in the first embodiment, hence descriptions thereof will be omitted.

Next, as shown in FIG. 52, for example, the P+ layer 3081P is formed on the front surface of the N-type well region 309N, and the P+ layer 3082P is formed on the back surface of the N-type well region 309N. The step of forming the P+ layer 3081P is performed by implanting a P-type impurity such as boron (B) from the exposed front surface of the semiconductor substrate 200, for example. The step of forming the P+ layer 3082P is performed by implanting a P-type impurity such as boron (B) from the exposed back surface of the semiconductor substrate 200, for example.

Manufacturing of the portion of the object circuit according to the modified example of the second embodiment is performed utilizing such back surface processing.

### Comparative Example

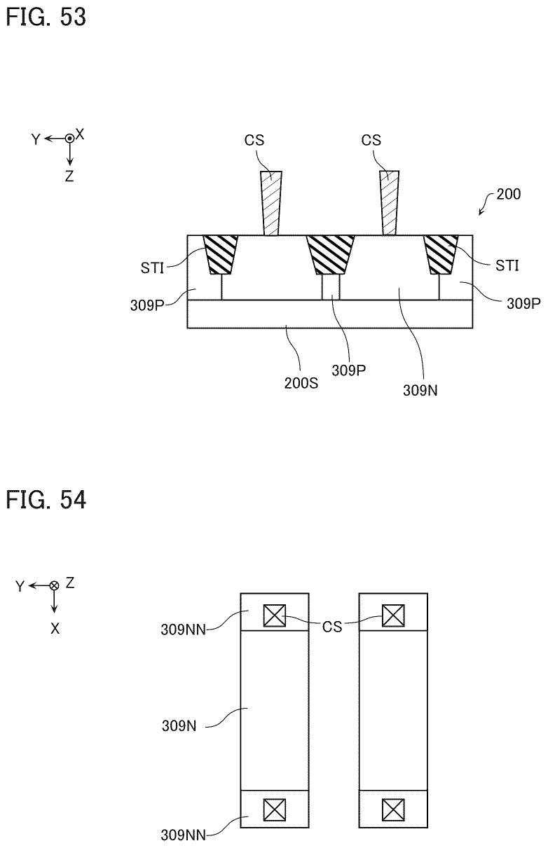

Next, a semiconductor memory device according to a comparative example will be described with reference to FIGS. 53 and 54. FIG. 53 is a schematic cross-sectional view showing a part of the configuration of the semiconductor memory device according to the comparative example. FIG. 54 is a schematic bottom view showing configuration of a resistance element shown in FIG. 53.

The semiconductor substrate 200 according to the comparative example is not provided with the insulating member DTI. Moreover, the semiconductor substrate 200 according to the comparative example is not provided with the P+ layer 3081P and P+ layer 3082P.

Note that although the N+ layer 309NN is not illustrated in FIG. 53, this is a schematic expression for description. As shown in FIG. 54, positions in the X-direction of the N+ layer 309NN and the via contact electrode CS connected thereto, coincide.

The N-type well region 309N according to the comparative example can be used as a resistor. That is, the N-type well region 309N according to the comparative example configures a well resistance. Each of a plurality of the N-type well regions 309N according to the comparative example functions as a resistance element connected between a pair of the via contact electrodes CS arranged in the X-direction, and has a certain resistance value (a fixed resistance value).

In the plurality of N-type well regions 309N according to the comparative example, joining (electrically connecting) two N-type well regions 309N in parallel enables their resistance value to be halved. Similarly, in the plurality of N-type well regions 309N according to the comparative example, joining (electrically connecting) two N-type well regions 309N in series enables their resistance value to be doubled. Changing a manner of joining the N-type well regions 309N in this way enables the numbers or lengths of N-type well regions 309N to be changed, and hence allows a variety of resistance values to be created.

However, when a plurality of the N-type well regions 309N according to the comparative example are utilized to create a variety of resistance values, a large number of the N-type well regions 309N need to be arranged, and circuit area increases.

### Advantages of Semiconductor Memory Device According to Modified Example of Second Embodiment

As described with reference to FIGS. 47 and 48, in a region between the insulating members DTI and the insulating members STI adjacent in the Y-direction viewed from the Z-direction, the semiconductor substrate 200 comprises: the P+ layer 3081P which includes a P-type impurity and is provided in the front surface of the semiconductor substrate 200; the N-type well region 309N which includes an N-type impurity and is provided on a back surface side of the P+ layer 3081P; and the P+ layer 3082P which includes a P-type impurity and is provided on a back surface side of the N-type well region 309N. The object circuit according to the modified example of the second embodiment is the N-type well region 309N configuring a well resistance.

Such a configuration results in that by voltages applied to the via contact electrodes CS electrically connected to the P+ layer 3081P and P+ layer 3082P being controlled by an unillustrated control circuit, the N-type well region 309N can have a resistance value that accords with the applied voltages.

Moreover, when a plurality of the N-type well regions 309N according to the modified example of the second embodiment are utilized to create a variety of resistance values, a plurality of resistance values can be expressed by a single N-type well region 309N, so there is no need for a large number of the N-type well regions 309N to be arranged, and an increase in circuit area can be suppressed.

### Configuration of VPGM Generating Circuit 940

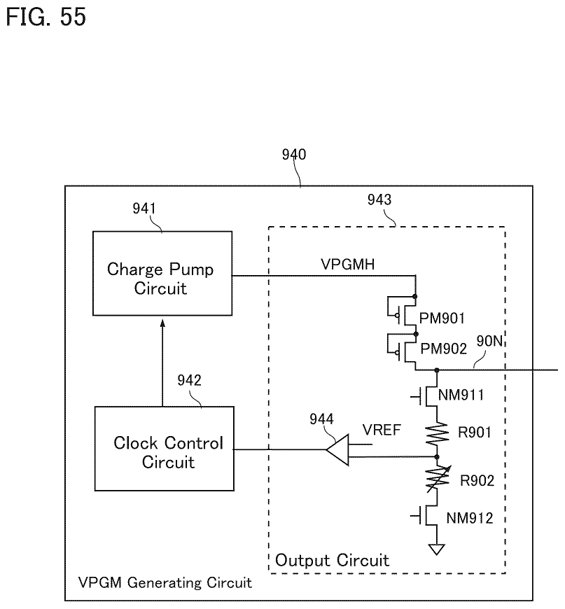

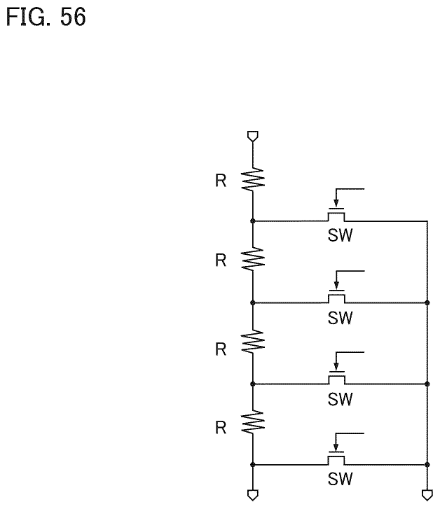

FIG. 55 is a block diagram showing an example of specific configuration of a VPGM generating circuit 940 in which the object circuit according to the second embodiment is used. FIG. 56 is a circuit diagram for explaining a ladder circuit.

The VPGM generating circuit 940, which is a circuit configuring the voltage generating circuit VG, generates a program voltage VPGM using output of a charge pump circuit 941.

The charge pump circuit 941 is a booster circuit that by accumulating a charge supplied thereto, can generate a voltage larger than a voltage supplied thereto. Output of the charge pump circuit 941 is supplied to an output circuit 943 as a voltage VPGMH. The voltage generating circuit VG generates a plurality of kinds of voltages required in the likes of a write operation and a read operation, from output of the charge pump circuit 941.

The output circuit 943 comprises two PMOS transistors PM901, PM902 whose current path is serially connected between a power supply line applied with the voltage VPGMH and an output node 90N. A source and gate of the transistor PM901 are connected to the power supply line. A source and gate of the transistor PM902 are connected to a drain of the transistor PM901, and a drain of the transistor PM902 is connected to the output node 90N, for example.

A current path of an NMOS transistor NM911, and a current path of a resistance R901, variable resistance R902, and NMOS transistor NM912 are serially connected between the output node 90N and a ground terminal. A connection point of the resistance R901 and the variable resistance R902 is connected to one input terminal of a comparator 944. The other input terminal of the comparator 944 is applied with a reference voltage VREF. The comparator 944 outputs a stop signal to a clock control circuit 942 in a period when voltage of the connection point of the resistance R901 and the variable resistance R902 is higher than the reference voltage VREF. The clock control circuit 942 is configured to stop generation of clock signals CLK,/CLK in a period when the stop signal is being outputted from the comparator 944. The transistors NM911, NM912, resistance R901, variable resistance R902, and comparator 944 configure a limit circuit.

The transistors PM901, PM902 are both diode-connected, and the voltage VPGMH applied to the output circuit 943 appears at output node 90N proportionally lowered by an amount of threshold voltages of the transistors PM901, PM902. By setting as the voltage VPGMH a voltage which is proportionally higher than the program voltage VPGM by an amount of threshold voltages of the transistors PM901, PM902, the program voltage VPGM can be generated from the output node 90N.

The transistors NM911, NM912 are supplied with control signals from the sequencer SQC (illustration of this omitted) to be ON in a period when the limit circuit is operated. In the period of the transistors NM911, NM912 being ON, the voltage appearing at output node 90N is divided by the resistance R901 and the variable resistance R902. Voltage of the connection point of the resistance R901 and the variable resistance R902 is compared with the reference voltage VREF by the comparator 944. The reference voltage VREF is set to a voltage of the connection point of the resistance R901 and the variable resistance R902 in the case of the voltage appearing at output node 90N being a prescribed program voltage VPGM. Therefore, when the voltage appearing at output node 90N exceeds the prescribed program voltage VPGM, then the voltage of the connection point of the resistance R901 and the variable resistance R902 will become higher than the reference voltage VREF, and the stop signal will be generated from the comparator 944. This stop signal causes the clock control circuit 942 to stop generation of the clock signals CLK, /CLK. As a result, output voltage of the charge pump circuit 941 falls, whereby voltage boosting of output node 90N is suppressed, and voltage of output node 90N is held at the prescribed program voltage VPGM.

In the output circuit 943 configured in this way, the diffusion resistance (P+ layer 306P) being the object circuit according to the second embodiment and the well resistance (N-type well region 309N) being the object circuit according to the modified example of the second embodiment are used as the variable resistance R902.

Note that the variable resistance R902 is conventionally realized by a ladder circuit having a ladder type resistance of the kind shown in FIG. 56. A resistance value of the ladder circuit of FIG. 56 is adjusted to a desired magnitude by switches SW being appropriately switched. In this respect, when the diffusion resistance (P+ layer 306P) being the object circuit according to the second embodiment and well resistance (N-type well region 309N) being the object circuit according to modified example of the second embodiment are utilized to create a variety of resistance values of the variable resistance R902, the plurality of resistance values can be expressed by a single diffusion resistance (P+ layer 306P) or single well resistance (N-type well region 309N), so the ladder circuit of FIG. 56 ceases to be required, and an increase in circuit area can be suppressed.

### Other Embodiments

That concludes description of the semiconductor memory devices according to the first through second embodiments, and modified example. However, the configurations described above are merely exemplifications, and specific configurations may be appropriately adjusted.

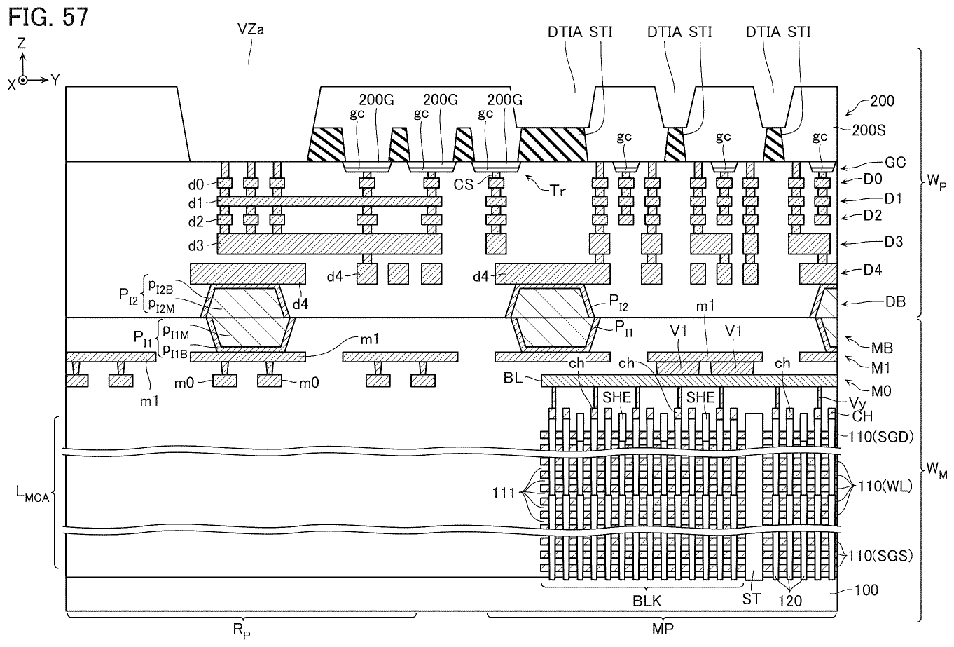

FIG. 57 is a schematic cross-sectional view for explaining a method of manufacturing a semiconductor substrate 200 portion of a chip C_{P} according to another embodiment.

Although in the method of manufacturing a semiconductor substrate 200 portion of the chip C_{P}, an example where the opening DTIA and the opening VZa are formed in separate steps has been described using FIGS. 26 and 28, the present invention is not limited to this. As shown in FIG. 57, for example, the opening DTIA and the opening VZa may be formed simultaneously. Note that, as mentioned above, this step is performed by a method such as RIE, for example.

Moreover, although in FIGS. 7 and 8, the bonding electrode P_{I2} and wiring d4 are connected unmediated by a via contact electrode, they may be connected via a via contact electrode.

Moreover, in the above embodiments, there have been described examples applied to a NAND flash memory. However, technology described in the present specification may also be applied to configurations of another semiconductor memory device such as a three-dimensional type NOR flash memory, for example. Moreover, technology described in the present specification may also be applied to configurations of a semiconductor device other than a semiconductor memory device.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising
a first semiconductor chip and a second semiconductor chip that are connected to each other, wherein
the first semiconductor chip comprises:
a semiconductor substrate having a first surface and a second surface, the first surface and the second surface intersecting a first direction;
a first insulating member that extends in the first direction from the first surface of the semiconductor substrate to a first position between the first surface and the second surface of the semiconductor substrate, and includes a first portion and a second portion, the first portion and the second portion being separated in a second direction intersecting the first direction;
a second insulating member that extends in the first direction from the second surface of the semiconductor substrate to the first position of the semiconductor substrate, and includes a third portion and a fourth portion, the third portion being provided at a position overlapping the first portion viewed from the first direction, and the fourth portion being provided at a position overlapping the second portion viewed from the first direction;
an object circuit provided in a region between the first portion and the second portion viewed from the first direction, of the semiconductor substrate;
a control circuit that adjusts electrical characteristics of the object circuit;
a plurality of transistors provided in the first surface of the semiconductor substrate;
a plurality of first contacts extending in the first direction and connected to the plurality of transistors; and
a plurality of first bonding electrodes electrically connected to the plurality of transistors via the plurality of first contacts,
the second semiconductor chip comprises:
a plurality of first conductive layers arranged in the first direction;
a semiconductor column extending in the first direction and facing the plurality of first conductive layers;
a plurality of second contacts extending in the first direction and connected to the plurality of first conductive layers; and
a plurality of second bonding electrodes connected to the plurality of first conductive layers via the plurality of second contacts, and
the first semiconductor chip and the second semiconductor chip is disposed so that the plurality of first bonding electrodes face the plurality of second bonding electrodes.

2. The semiconductor memory device according to claim 1, wherein
the object circuit is a first transistor provided in the first surface in a region surrounded by the first insulating member viewed from the first direction, of the semiconductor substrate,
a part of the plurality of transistors is provided at a different position from the region surrounded by the first insulating member viewed from the first direction, of the semiconductor substrate, and
the first transistor and the part of the plurality of transistors are electrically connected.

3. The semiconductor memory device according to claim 2, wherein the first transistor is an N-channel MOS transistor.

4. The semiconductor memory device according to claim 2, wherein
the first semiconductor chip comprises a third contact extending in the first direction and connected to the first surface of the semiconductor substrate,
the region surrounded by the first insulating member, of the semiconductor substrate comprises:
a first region including an impurity of a first conductive type; and
a second region provided in a connecting portion to the third contact, of the first surface, and including the impurity of the first conductive type, and
a concentration of the impurity of the first conductive type in the second region is higher than a concentration of the impurity of the first conductive type in the first region.

5. The semiconductor memory device according to claim 2, wherein
the first insulating member further comprises a fifth portion provided on an opposite side to the second insulating member with respect to the first insulating member, viewed from the first direction,
the second insulating member further comprises a sixth portion provided at a position overlapping the fifth portion viewed from the first direction, and
the part of the plurality of transistors is provided in a region between the first portion and the fifth portion viewed from the first direction, of the semiconductor substrate.

6. The semiconductor memory device according to claim 5, wherein
the part of the plurality of transistors includes an N-channel MOS transistor and a P-channel MOS transistor.

7. The semiconductor memory device according to claim 5, wherein
the region between the first portion and the fifth portion viewed from the first direction, of the semiconductor substrate comprises: a third region including an impurity of a first conductive type; and a well region including an impurity of a second conductive type different from the first conductive type, and
the part of the plurality of transistors includes a second transistor provided in the third region and a third transistor provided in the well region.

8. The semiconductor memory device according to claim 7, wherein
the first semiconductor chip comprises a fourth contact extending in the first direction and connected to the first surface of the semiconductor substrate,
the well region comprises:
a fourth region including the impurity of the second conductive type; and
a fifth region provided in a connecting portion to the fourth contact, of the first surface, and including the impurity of the second conductive type, and
a concentration of the impurity of the second conductive type in the fifth region is higher than a concentration of the impurity of the second conductive type in the fourth region.

9. The semiconductor memory device according to claim 2, wherein
the control circuit is able to control a voltage applied to a body of the first transistor independently of a voltage applied to a body of the part of the plurality of transistors.

10. The semiconductor memory device according to claim 9, wherein
the control circuit controls a threshold voltage of the first transistor by controlling the voltage applied to the body of the first transistor.

11. The semiconductor memory device according to claim 1, wherein
the object circuit is a resistance element provided in the first surface in a region surrounded by the first insulating member and the second insulating member viewed from the first direction, of the semiconductor substrate, and
the control circuit is able to control a resistance value of the resistance element.

12. The semiconductor memory device according to claim 11, wherein
the semiconductor substrate comprises a first semiconductor region surrounded by the first insulating member and the second insulating member viewed from the first direction and including an impurity of a first conductive type,
the first semiconductor region comprises:
a first region provided in the first surface and including the impurity of the first conductive type; and
a second region provided on a second surface side of the first region and including an impurity of a second conductive type different from the first conductive type,
a concentration of the impurity of the first conductive type in the first region is higher than a concentration of the impurity of the first conductive type in the first semiconductor region, and
the resistance element is configured by the first region.

13. The semiconductor memory device according to claim 12, wherein
the first semiconductor chip comprises:
a third contact extending in the first direction and connected to the first region from a first surface side of the semiconductor substrate; and
a fourth contact extending in the first direction and connected to the second region from a second surface side of the semiconductor substrate.

14. The semiconductor memory device according to claim 13, wherein
the control circuit controls the resistance value of the resistance element by controlling a voltage applied to the fourth contact.

15. The semiconductor memory device according to claim 14, wherein
the control circuit controls the resistance value of the resistance element to two values by controlling the voltage applied to the fourth contact to two values.

16. The semiconductor memory device according to claim 11, wherein
the semiconductor substrate includes an impurity of a first conductive type, and, in a first region surrounded by the first insulating member and the second insulating member viewed from the first direction, comprises:
a second region provided in the first surface and including the impurity of the first conductive type;
a third region provided on a second surface side of the second region and including an impurity of a second conductive type different from the first conductive type; and
a fourth region provided on a second surface side of the third region and including the impurity of the first conductive type,
a concentration of the impurity of the first conductive type in the second region and a concentration of the impurity of the first conductive type in the fourth region are higher than a concentration of the impurity of the first conductive type in the semiconductor substrate, and
the resistance element is configured by the third region.

17. The semiconductor memory device according to claim 16, wherein
the first semiconductor chip comprises:
a third contact extending in the first direction and connected to the second region from a first surface side of the semiconductor substrate; and
a fourth contact extending in the first direction and connected to the fourth region from a second surface side of the semiconductor substrate.

18. The semiconductor memory device according to claim 17, wherein
the control circuit controls the resistance value of the resistance element by controlling a voltage applied to the third contact and the fourth contact.

19. The semiconductor memory device according to claim 18, wherein
the control circuit controls the resistance value of the resistance element to two values by controlling the voltage applied to the third contact and the fourth contact to two values.
